(19) United States
(12) Patent Application Publication
(10) Pub. No.: US 2020/0411515 A1
(43) Pub. Date: Dec. 31, 2020

(54) INTEGRATED CIRCUIT SEMICONDUCTOR DEVICE

(71) Applicant: SAMSUNG ELECTRONICS CO., LTD., SUWON-SI (KR)

(72) Inventors: HOJUN KIM, Suwon-si (KR); Namhyun LEE, Suwon-si (KR)

(21) Appl. No.: 16/780,981

(22) Filed: Feb. 4, 2020

(30) Foreign Application Priority Data
Jun. 25, 2019 (KR) 10-2019-0075788

(51) Int. Cl. H01L 27/088; H01L 29/786; H01L 29/423; H01L 29/78

(52) U.S. Cl. CPC H01L 27/0886; H01L 29/7851; H01L 29/42392; H01L 29/78696

(57) ABSTRACT

An integrated circuit semiconductor device including: a multi-bridge channel type transistor in a first region of a substrate, wherein the multi-bridge channel type transistor includes a nanosheet stack structure on the substrate, a first gate dielectric layer on the nanosheet stack structure, and a first gate electrode on the first gate dielectric layer; and a fin-type transistor in a second region of the substrate, wherein the fin-type transistor includes an active fin on the substrate, a second gate dielectric layer on the active fin, and a second gate electrode on the second gate dielectric layer, wherein a width of the nanosheet stack structure is greater than a width of the active fin.

### CROSS-REFERENCE TO RELATED APPLICATION

This application claims priority under 35 U.S.C. § 119 to Korean Patent Application No. 10-2019-0075788, filed on Jun. 25, 2019, in the Korean Intellectual Property Office, the disclosure of which is incorporated by reference herein in its entirety.

### TECHNICAL FIELD

The inventive concept relates to an integrated circuit semiconductor device, and more particularly, to an integrated circuit semiconductor device including a plurality of transistors.

### DISCUSSION OF RELATED ART

Integrated circuit semiconductor devices employ transistors that operate at low voltages and transistors that operate at high voltages. As semiconductor devices become more integrated, three-dimensional transistors are used. However, three-dimensional transistors that operate at high and low voltages may not be reliably formed on a substrate.

### SUMMARY

According to an exemplary embodiment of the inventive concept, there is provided an integrated circuit semiconductor device, comprising: a multi-bridge channel type transistor in a first region of a substrate, wherein the multi-bridge channel type transistor comprises a nanosheet stack structure on the substrate, a first gate dielectric layer on the nanosheet stack structure, and a first gate electrode on the first gate dielectric layer; and a fin-type transistor in a second region of the substrate, wherein the fin-type transistor comprises an active fin on the substrate, a second gate dielectric layer on the active fin, and a second gate electrode on the second gate dielectric layer, wherein a width of the nanosheet stack structure is greater than a width of the active fin.

According to an exemplary embodiment of the inventive concept, there is provided an integrated circuit semiconductor device, comprising: a multi-bridge channel type transistor in a first region of a substrate, wherein the multi-bridge channel type transistor comprises a first field sub-fin extending on the substrate in a first direction, a nanosheet stack structure on the first field sub-fin, a first gate dielectric layer on the nanosheet stack structure, and a first gate electrode extending on the first gate dielectric layer in a second direction perpendicular to the first direction; and a fin-type transistor in a second region of the substrate, wherein the fin-type transistor comprises a second field sub-fin extending in the first direction, an active fin extending on the second field sub-fin in the first direction, a second gate dielectric layer on the active fin, and a second gate electrode extending on the second gate dielectric layer in the second direction, wherein a width of the nanosheet stack structure in the second direction is greater than a width of the active fin in the second direction.

According to an exemplary embodiment of the inventive concept, there is provided an integrated circuit semiconductor device, comprising: a multi-bridge channel type transistor in a first region of a substrate, wherein the multi-bridge channel type transistor comprises a first field sub-fin extending on the substrate in a first direction, a first gate electrode extending on the first field sub-fin in a second direction perpendicular to the first direction, a nanosheet stack structure overlapping an area where the first field sub-fin and the first gate electrode cross each other, and a first gate dielectric layer between nanosheets of the nanosheet stack structure and the first gate electrode; and a fin-type transistor in a second region of the substrate, wherein the fin-type transistor comprises a second field sub-fin extending on the substrate in the first direction, a second gate electrode extending on the second field sub-fin in the second direction, an active fin overlapping an area where the second field sub-fin and the second gate electrode cross each other, and a second gate dielectric layer between the active fin and the second gate electrode, wherein a width of the nanosheet stack structure in the second direction is greater than a width of the active fin in the second direction.

According to an exemplary embodiment of the inventive concept, there is provided an integrated circuit semiconductor device, comprising: a first transistor in a first region of a substrate, wherein the first transistor comprises a plurality of nanosheets stacked in a first direction; and a second transistor in a second region of the substrate, wherein the second transistor comprises an active fin, wherein a width of a first nanosheet of the plurality nanosheets in a second direction perpendicular to the first direction is greater than a width of the active fin in the second direction.

### BRIEF DESCRIPTION OF THE DRAWINGS

The above and other features of the inventive concept will be more clearly understood by describing in detail exemplary embodiments thereof in conjunction with the accompanying drawings in which:

FIG. 1 is a layout diagram of an integrated circuit semiconductor device according to an exemplary embodiment of the inventive concept;

FIG. 2 is a cross-sectional view taken along lines IIa-IIa′ and IIb-IIb′ of the integrated circuit semiconductor device of FIG. 1;

FIG. 3 is a cross-sectional view taken along lines IIIa-IIIa′ and IIIb-IIIb′ of the integrated circuit semiconductor device of FIG. 1;

FIGS. 4, 5, 6, 7, 8, 9 and 10 are cross-sectional views illustrating a method of manufacturing the integrated circuit semiconductor device of FIG. 2, according to an exemplary embodiment of the inventive concept;

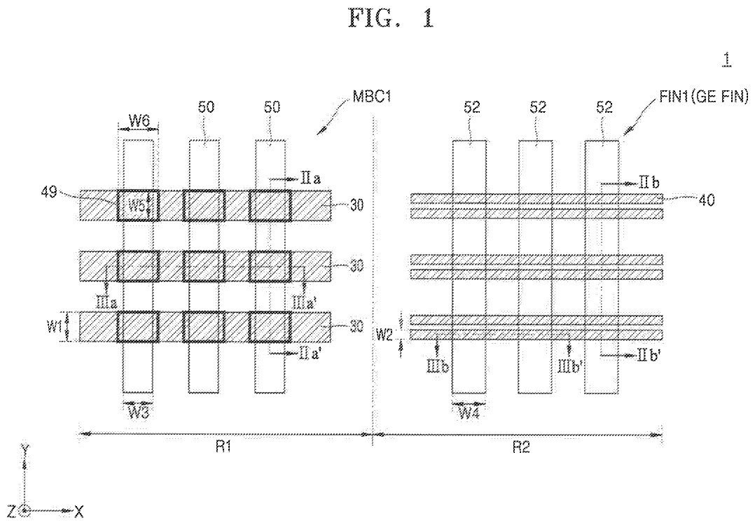

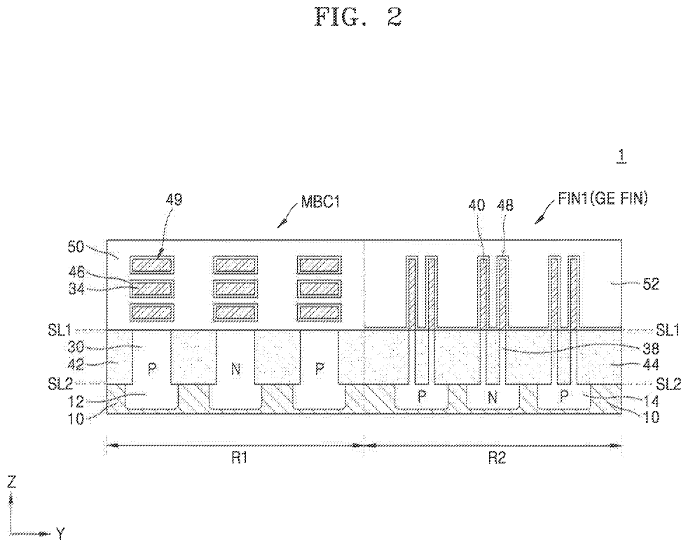

FIGS. 1A, 11B, 11C and 1D are cross-sectional views illustrating a process of manufacturing the integrated circuit semiconductor device of FIG. 5, according to an exemplary embodiment of the inventive concept;

FIGS. 12A, 12B, 12C and 12D are cross-sectional views illustrating a process of manufacturing the integrated circuit semiconductor device of FIG. 5, according to an exemplary embodiment of the inventive concept;

FIGS. 13A, 13B, 13C and 13D are cross-sectional views illustrating a process of manufacturing the integrated circuit semiconductor device of FIG. 5, according to an exemplary embodiment of the inventive concept;

FIG. 14 is a layout diagram of an integrated circuit semiconductor device according to an exemplary embodiment of the inventive concept;

FIG. 15 is a cross-sectional view taken along lines XVa-XVa′ and XVb-XVb′ of the integrated circuit semiconductor device of FIG. 14;

FIG. 16 is a cross-sectional view taken along lines XVIa-XVIa′ and XVIb-XVIb′ of the integrated circuit semiconductor device of FIG. 14;

FIGS. 17, 18, 19, 20, 21, 22, 23 and 24 are cross-sectional views illustrating a method of manufacturing the integrated circuit semiconductor device of FIG. 15, according to an exemplary embodiment of the inventive concept;

FIGS. 25, 26, 27 and 28 are cross-sectional views illustrating a method of manufacturing the integrated circuit semiconductor device of FIG. 15, according to an exemplary embodiment of the inventive concept;

FIGS. 29A and 29B are cross-sectional views of an integrated circuit semiconductor device according to an exemplary embodiment of the inventive concept;

FIG. 30 is a block diagram of a semiconductor chip including an integrated circuit semiconductor device according to exemplary embodiments of the inventive concept;

FIG. 31 is a block diagram of a semiconductor chip including an integrated circuit semiconductor device according to exemplary embodiments of the inventive concept;

FIG. 32 is a block diagram of an electronic device including an integrated circuit semiconductor device according to exemplary embodiments of the inventive concept; and

FIG. 33 is an equivalent circuit diagram of a static random access memory (SRAM) cell according to exemplary embodiments of the inventive concept.

### DETAILED DESCRIPTION OF THE EMBODIMENTS

Hereinafter, exemplary embodiments of the inventive concept will be described in detail by referring to the accompanying drawings. As those skilled in the art would realize, the described embodiments may be modified in various different ways, and thus, should not be limited to the embodiments set forth herein.

FIG. 1 is a layout diagram of an integrated circuit semiconductor device 1 according to an exemplary embodiment of the inventive concept.

For example, the integrated circuit semiconductor device 1 may include a first region R1 and a second region R2 on a substrate. In some exemplary embodiments of the inventive concept, the first region R1 may include a logic cell region operating at a low voltage, for example, a voltage less than 1 volt (V). The logic cell region may be a region in which a first multi-bridge channel transistor MBC1 is formed. The first multi-bridge channel transistor MBC1 may include a metal-oxide semiconductor (MOS) transistor.

The second region R2 may be an input/output region operating at a high voltage, for example, a voltage equal to or greater than 1 V. The input/output region may include a first fin-type transistor FIN1. The first fin-type transistor FIN1 may be a general fin-type transistor GE FIN. The general fin-type transistor GE FIN may include a transistor other than a zebra fin-type transistor described below.

In FIG. 1, a first direction (X direction) may be a channel length direction, and a second direction (Y direction) may be a channel width direction. Hereinafter, the layout of the integrated circuit semiconductor device 1 will be described in more detail. It is to be understood, however, that the inventive concept is not limited to the layout of FIG. 1.

The first multi-bridge channel transistor MBC1 in the first region R1 may include a first field sub-fin 30 extending in the first direction. The first field sub-fin 30 may be provided as an active region of the first multi-bridge channel transistor MBC1. A plurality of first field sub-fins 30 may be provided. For example, the first field sub-fins 30 may be spaced apart from each other in the second direction. The first field sub-fin 30 may have a first width W1 on a plane in the second direction. A channel width of the first multi-bridge channel transistor MBC1 may be adjusted by adjusting the first width W1.

A first gate electrode 50 extends in the second direction (Y direction) perpendicular to the first direction on the first field sub-fin 30. A plurality of first gate electrodes 50 may be provided. For example, the first gate electrodes 50 may be spaced apart from each other in the first direction. The first gate electrode 50 may have a third width W3 on the plane in the first direction. The channel length of the first multi-bridge channel transistor MBC1 may be adjusted by adjusting the third width W3.

A nanosheet stack structure 49 may be located in an area where the first field sub-fin 30 and the first gate electrode 50 cross each other in the first region R1. The nanosheet stack structure 49 may have a fifth width W5 and a sixth width W6 on the plane in the second direction and the first direction, respectively. The fifth width W5 may be equal to the first width W1 of the first field sub-fin 30. The first width W1 and the fifth width W5 may be about 15 nm to about 50 nm. The sixth width W6 may be greater than the third width W3 of the first gate electrode 50 on the plane in the first direction.

The channel width of the first multi-bridge channel transistor MBC1 may be adjusted by adjusting the fifth width W5. The channel length of the first multi-bridge channel transistor MBC1 may be adjusted by adjusting the sixth width W6. The fifth width W5 of the nanosheet stack structure 49 on the plane in the second direction may be greater than a second width W2 of an active fin 40 of the second region R2 on the plane in the second direction. The active fin 40 having the second width W2 will be described below.

The current driving capability of the first multi-bridge channel transistor MBC1 may be changed by adjusting the first width W, the third width W3, the fifth width W5, and the sixth width W6 on the plane. Although the planar shape of the nanosheet stack structure 49 is illustrated as being substantially rectangular, the inventive concept is not limited thereto. For example, the planar shape of the nanosheet stack structure 49 may be circular.

The first fin-type transistor FIN1 of the second region R2 may include an active fin 40 extending in the first direction. As described below, a second field sub-fin 38 extending in the first direction may be located below the active fin 40. The active fin 40 may be provided as an active region of the first fin-type transistor FIN1. As described below, the active fin 40 may be at a higher level than the first field sub-fin 30 in a third direction (Z direction) perpendicular to the surface of the substrate. The active fin 40 may have a second width W2 in the second direction. The channel width of the first fin-type transistor FIN1 may be adjusted by adjusting the second width W2 of the active fin 40.

The second width W2 of the active fin 40 may be different from the first width W1 of the first field sub-fin 30 on the plane. In some exemplary embodiments of the inventive concept, the second width W2 of the active fin 40 may be less than the first width W1 of the first field sub-fin 30. In addition, the second width W2 of the active fin 40 on the plane in the second direction may be less than the fifth width W5 of the nanosheet stack structure 49 of the first region R1 on the plane in the second direction.

In some exemplary embodiments of the inventive concept, the active fin 40 may include two active fins spaced apart from each other. In other words, the active fin 40 may include a pair of active fins spaced apart from each other and a plurality of pairs of active fins may be spaced apart from each other along the second direction. The fifth width W5 of the nanosheet stack structure 49 on the plane in the second direction may be greater than or equal to the sum (e.g., W2+W2) of the widths of the two active fins on the plane in the second direction.

A second gate electrode 52 extends on the active fin 40 in the second direction (Y direction) perpendicular to the first direction. A plurality of second gate electrodes 52 may be spaced apart from each other along the first direction. The second gate electrode 52 may have a fourth width W4 in the first direction. The channel length of the first fin-type transistor FIN1 may be adjusted by adjusting the fourth width W4 of the second gate electrode 52.

In some exemplary embodiments of the inventive concept, the fourth width W4 of the second gate electrode 52 may be different from the third width W3 of the first gate electrode 50. In some exemplary embodiments of the inventive concept, the fourth width W4 of the second gate electrode 52 may be greater than the third width W3 of the first gate electrode 50. The fourth width W4 of the second gate electrode 52 may be greater than the third width W3 of the first gate electrode 50. Therefore, the first fin-type transistor FIN1 operates at a higher voltage than the first multi-bridge channel transistor MBC1. The current driving capability of the first fin-type transistor FIN1 may be changed by adjusting the second width W2 and the fourth width W4.

In the integrated circuit semiconductor device 1 described above, the first multi-bridge channel transistor MBC1 of a three-dimensional transistor is formed in the first region R1 on the substrate, in other words, a low voltage operating region. In addition, the first fin-type transistor FIN1 of the three-dimensional transistor, for example, a general fin-type transistor GE FIN is formed in the second region R2 on the substrate, in other words, a high voltage operating region. Accordingly, in the integrated circuit semiconductor device 1 according to the present embodiment, three-dimensional transistors operating at a high voltage and a low voltage may be reliably formed. This will be described in more detail below.

FIG. 2 is a cross-sectional view taken along lines IIa-IIa′ and IIb-IIb′ of the integrated circuit semiconductor device 1 of FIG. 1.

For example, the integrated circuit semiconductor device 1 may include the first multi-bridge channel transistor MBC1 and the first fin-type transistor FIN in the first region R1 and the second region R2 of the substrate (e.g., substrate 10), respectively. As described above, the first fin-type transistor FIN1 may be a general fin-type transistor GE FIN.

A first well region 12 may be formed in the first region R1 of the substrate 10. The first well region 12 may include a P-type well region, an N-type well region, and a P-type well region in the second direction (Y direction). The substrate 10 may include a semiconductor material such as silicon, germanium, or silicon-germanium, or a Group III-V semiconductor compound such as GaP, GaAs, or GaSb.

In the first region R1, the first field sub-fin 30 protruding from the surface of the substrate 10 in the third direction (Z direction) may be formed. The first field sub-fin 30 may be formed on the first well region 12. The first field sub-fin 30 may have the same conductivity type as the first well region 12. The first field sub-fin 30 may include the same body as the substrate 10. The first field sub-fin 30 protrudes from a second level SL2 to a first level SL1 in the third direction (Z direction) on the substrate 10. The first level SL may be a level near the surface of the substrate 10, as described below.

A first device isolation layer 42 may be formed on the substrate 10. The first device isolation layer 42 may be formed around the first field sub-fin 30. The first device isolation layer 42 may not be formed on top of the first field sub-fin 30. The first device isolation layer 42 may include a silicon oxide film, a silicon nitride film, or a combination thereof.

The nanosheet stack structure 49 is formed on the first field sub-fin 30. The nanosheet stack structure 49 may be at the same level as the active fin 40 of the second region R2 in the third direction (Z direction), in other words, in a direction perpendicular to the surface of the substrate 10. The nanosheet stack structure 49 includes a plurality of first nanosheets 34 spaced apart from each other in the third direction.

In FIG. 2, three first nanosheets 34 are stacked, but more or less nanosheets may be stacked. The number of nanosheets 34 is not limited. Each of the first nanosheets 34 may include a silicon layer. A first gate dielectric layer 46 is formed to surround the first nanosheets 34. The first gate electrode 50 is formed on the first gate dielectric layer 46.

A second well region 14 may be formed in the second region R2 of the substrate 10. The second well region 14 may include a P-type well region, an N-type well region, and a P-type well region in the second direction (Y direction).

In the second region R2, the second field sub-fin 38 protruding from the surface of the substrate 10 in the third direction (Z direction) may be formed. The second field sub-fin 38 may be formed on the second well region 14. The second field sub-fin 38 may have the same conductivity type as the second well region 14. Although it is shown in FIG. 2 that two second field sub-fins 38 are formed in one second well region 14, one or more second field sub-fins 38 may be formed therein. For example, three second field sub-fins 38 may be formed over one of the P-type well regions of the second well region 14. The number of second field sub-fins 38 formed in the second well region 14 is not limited.

The second field sub-fin 38 may include the same body as the substrate 10. The second field sub-fin 38 may include a fin type active pattern. The second field sub-fin 38 protrudes from the second level SL2 to the first level SL1 in the third direction (Z direction) on the substrate 10. The second field sub-fin 38 may be at the same level as the first field sub-fin 30 of the first region R1 in a direction perpendicular to the surface of the substrate 10. The first level SL1 may be a level near the surface of the substrate 10, as described below.

A second device isolation layer 44 may be formed on the substrate 10. The second device isolation layer 44 may be formed around the second field sub-fin 38. The second device isolation layer 44 may include the same material as the first device isolation layer 42.

The active fin 40, which is connected to the second field sub-fin 38, is formed on the second field sub-fin 38 in the third direction (Z direction), in other words, the direction perpendicular to the surface of the substrate 10. The active fin 40 may include a different body than the substrate 10 or the second field sub-fin 38.

The active fin 40 may be a general fin including a single semiconductor layer, for example, a silicon layer. The active fin 40 may include an epitaxial layer, for example, a silicon epitaxial layer. The active fin 40 protrudes from the first level SL1 in the third direction (Z direction) with respect to the surface of the substrate 10. The active fin 40 protrudes from the surface of the second device isolation layer 44 in the third direction (Z direction).

The active fin 40 is at a higher level than the first field sub-fin 30 of the first region R1 in the third direction (Z direction), in other words, the direction perpendicular to the surface of the substrate 10. The active fin 40 may include a silicon layer. A second gate dielectric layer 48 is formed on the surface and side surface of the active fin 40. The second gate electrode 52 is formed on the second gate dielectric layer 48.

In some exemplary embodiments of the inventive concept, the first gate dielectric layer 46 of the first region R1 and the second gate dielectric layer 48 of the second region R2 may be simultaneously formed in a manufacturing process. When the first gate dielectric layer 46 and the second gate dielectric layer 48 are formed simultaneously or separately, the first gate dielectric layer 46 may be easily formed in a space between the first nanosheets 34 because the active fin 40 is in the form of a fin.

In some exemplary embodiments of the inventive concept, the first gate dielectric layer 46 and the second gate dielectric layer 48 may be high dielectric layers having a higher dielectric constant than the silicon oxide layer. For example, each of the first gate dielectric layer 46 and the second gate dielectric layer 48 may include at least one selected from hafnium oxide (HfO₂), hafnium silicate (HfSiO), hafnium oxynitride (HfON), hafnium silicon oxynitride (HSiON), hafnium aluminum oxide (HfAlO₃), lanthanum oxide (LaO), lanthanum aluminum oxide (LaAO), zirconium oxide (ZrO), zirconium silicate (ZrSiO), zirconium oxynitride (ZrON), zirconium silicon oxynitride (ZrSiON), titanium oxide (TiO₂), barium strontium titanium oxide (BaSrTiO), barium titanium oxide (BaTiO), strontium titanium oxide (SrTiO), yttrium oxide (YO), aluminum oxide (Al₂O₃), tantalum oxide (Ta₂O₃), and lead scandium tantalum oxide (PbScTaO).

In some exemplary embodiments of the inventive concept, the first gate electrode 50 of the first region R1 and the second gate electrode 52 of the second region R2 may be simultaneously formed in a manufacturing process. In some exemplary embodiments of the inventive concept, each of the first gate electrode 50 and the second gate electrode 52 may include metal or metal nitride. In an exemplary embodiment of the inventive concept, each of the first gate electrode 50 and the second gate electrode 52 may include Ti, TiN, Ta, TaN, TiAC, TiAlCN, TiAlSiCN, cobalt, tungsten, or the like.

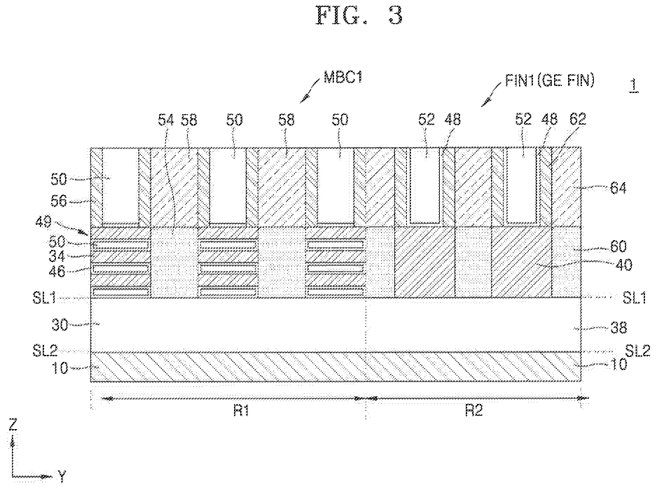

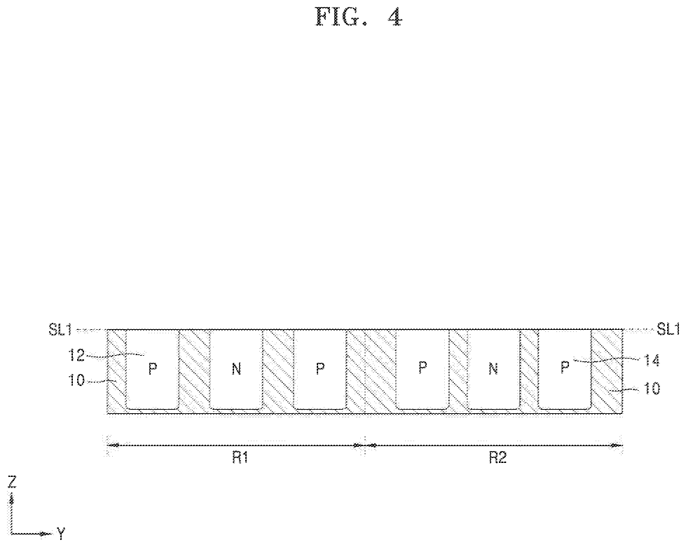

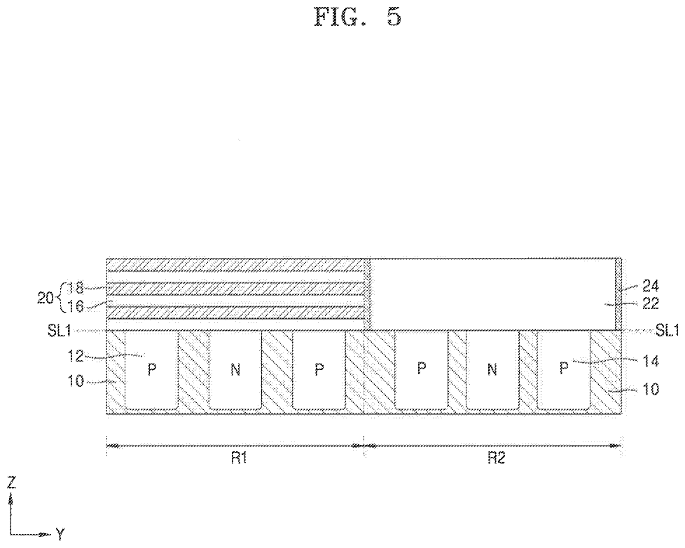

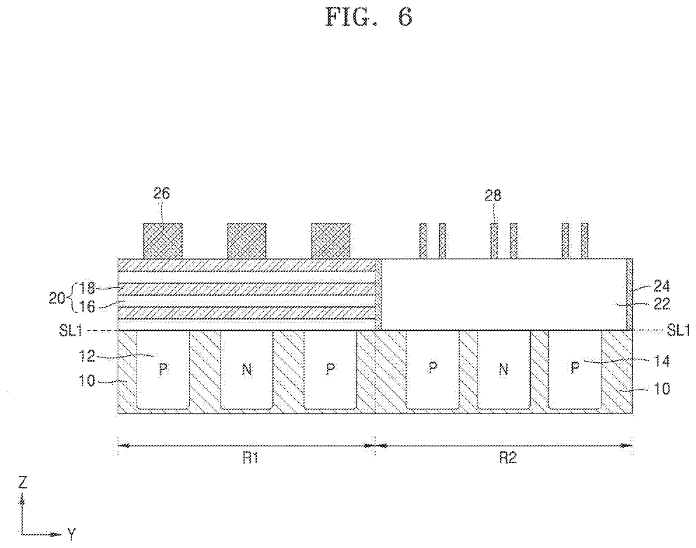

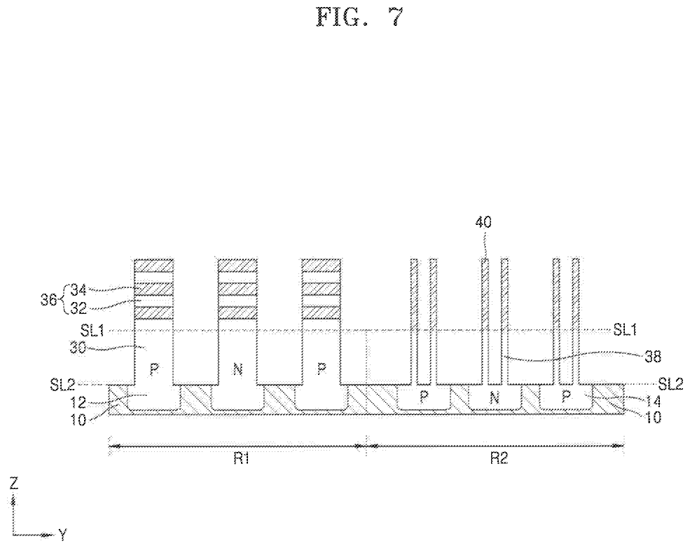

FIG. 3 is a cross-sectional view taken along lines IIIa-IIIa′ and IIIb-IIIb′ of the integrated circuit semiconductor device of FIG. 1.

Hereinafter, the descriptions given with reference to FIG. 2 are briefly provided or omitted. The first field sub-fin 30 may be located on the substrate 10 in the first region R. The substrate 10 may include the first well region 12 of FIG. 2, for example, an N-type region. The first active fin, in other words, the first field sub-fin 30, may be a fin of the same conductivity type as the first well region 12. The first field sub-fin 30 may include the same material as the substrate 10. The first field sub-fin 30 is formed on the substrate 10 from the second level SL2 to the first level SL1 in the third direction (Z direction). The first level SL1 may be a level near the surface of the substrate 10.

The nanosheet stack structure 49 is formed on the first field sub-fin 30. The nanosheet stack structure 49 includes a plurality of nanosheets 34 spaced apart from each other in the third direction (Z direction). The first gate dielectric layer 46 is formed to surround the nanosheets 34. The first gate electrode 50 is formed on the first gate dielectric layer 46, between the nanosheets 34, and on the nanosheets 34.

In some exemplary embodiments of the inventive concept, a first gate spacer 56 may be formed on both sidewalls of the first gate electrode 50. A first source and drain region 54 may be formed under both sides of the first gate electrode 50 and on both sides of the nanosheet stack structure 49. A first interlayer insulating layer 58 may be formed around the first gate electrode 50 and the first gate spacer 56.

The second field sub-fin 38 may be located on the substrate 10 in the second region R2. The second field sub-fin 38 may include a fin type active pattern. The second field sub-fin 38 is formed on the substrate 10 from the second level SL2 to the first level SL1 in the third direction (Z direction). The substrate 10 may include the second well region 14 of FIG. 2, for example, a P-type region. The second field sub-fin 38 may be the same conductivity type as the second well region 14.

An active fin 40 is formed on the second field sub-fin 38. The active fin 40 may be a general active fin. The active fin 40 may be at a level higher than the first field sub-fin 30 of the first region R1 in the third direction (Z direction), in other words, the direction perpendicular to the surface of the substrate 10. A second gate dielectric layer 48 is formed on a region of the active fin 40. A second gate electrode 52 is formed on the second gate dielectric layer 48.

In some exemplary embodiments of the inventive concept, the second gate dielectric layer 48 may also be formed on both sidewalls of the second gate electrode 52. In some exemplary embodiments of the inventive concept, a second gate spacer 62 may be formed around the second gate electrode 52. In some exemplary embodiments of the inventive concept, the second gate spacer 62 may not be formed in the second region R2. Second source and drain regions 60 may be formed below the second gate electrode 52 and on both sides of the active fin 40. A second interlayer insulating layer 64 may be formed around the second gate electrode 52 and the second gate spacer 62.

FIGS. 4 to 10 are cross-sectional views illustrating a method of manufacturing the integrated circuit semiconductor device of FIG. 2, according to an exemplary embodiment of the inventive concept.

For example, in FIGS. 4 to 10, reference numerals that are the same as those of FIGS. 1 and 2 denote elements that are the same as those of FIGS. 4 to 10. Thus, the same descriptions as those given with reference to FIGS. 1 and 2 are briefly provided or omitted.

Referring to FIG. 4, a first well region 12 and a second well region 14 are formed in the first region R1 and the second region R2 of the substrate 10, respectively. Each of the first well region 12 and the second well region 14 may include a P-type well region, an N-type well region, and a P-type well region separated from each other. The upper surface of the substrate 10 may correspond to the first level SL1.

Referring to FIG. 5, a semiconductor stack material layer 20, in which a first semiconductor layer 16 and a nanosheet semiconductor layer 18 are alternately stacked, is formed in the first region R1 of the substrate 10. The semiconductor stack material layer 20 may be formed on the first level SL1 of the substrate 10. The first semiconductor layer 16 and the nanosheet semiconductor layer 18 may be formed by an epitaxial growth method. The first semiconductor layer 16 and the nanosheet semiconductor layer 18 may include different semiconductor materials.

In some exemplary embodiments of the inventive concept, the first semiconductor layer 16 may include SiGe and the nanosheet semiconductor layer 18 may include Si, but they are not limited thereto. The first semiconductor layer 16 may include a material that is etched with respect to the nanosheet semiconductor layer 18. The first semiconductor layer 16 and the nanosheet semiconductor layer 18 may have the same thickness, but the inventive concept is not limited thereto.

An active semiconductor layer 22 is formed in the second region R2 of the substrate 10. The active semiconductor layer 22 may be formed by an epitaxial growth method. In the second region R2, the active semiconductor layer 22 may be formed in a liner layer 24 on the substrate 10. The active semiconductor layer 22 may be separated from the semiconductor stack material layer 20 of the first region R1 by the liner layer 24.

In some exemplary embodiments of the inventive concept, the liner layer 24 may include a silicon nitride layer. In some exemplary embodiments of the inventive concept, the liner layer 24 may include a silicon oxide layer. In some exemplary embodiments of the inventive concept, the active semiconductor layer 22 may include a silicon layer. In some exemplary embodiments of the inventive concept, the liner layer 24 may not be formed, and only the active semiconductor layer 22 may be formed. A manufacturing process of forming the liner layer 24 and the active semiconductor layer 22 in the second region R2 is described in more detail below.

Referring to FIG. 6, a first mask pattern 26 is formed on the semiconductor stack material layer 20 of the first region R1. The first mask pattern 26 is formed on an uppermost nanosheet semiconductor layer 18 in the semiconductor stack material layer 20. A second mask pattern 28 is formed on the active semiconductor layer 22 of the second region R2. For example, the second mask pattern 28 is formed between the liner layer 24.

In some exemplary embodiments of the inventive concept, each of the first mask pattern 26 and the second mask pattern 28 may include a hard mask pattern. The hard mask pattern may include silicon nitride, polysilicon, a spin-on hardmask (SOH) material, or a combination thereof, but it is not limited thereto.

Referring to FIG. 7, in the first region R, the semiconductor stack material layer 20 is etched using the first mask pattern 26 as an etch mask, thereby forming a semiconductor stack pattern 36 and a first field sub-fin 30. The semiconductor stack pattern 36 may have a stacked structure in which a first semiconductor pattern 32 and a nanosheet 34 are stacked. The nanosheet 34 may include the nanosheet semiconductor layer 18.

The first field sub-fin 30 may be formed by etching a portion of the substrate 10. In the first region R1, the first field sub-fin 30 may be an active region. The semiconductor stack pattern 36 may be formed on the first field sub-fin 30.

In the second region R2, the active semiconductor layer 22 is etched using the second mask pattern 28 as an etch mask to form the active fin 40 and the second field sub-fin 38. The active fin 40 may include the active semiconductor layer 22. The second field sub-fin 38 may include an active pattern. The active fin 40 may be formed on the second field sub-fin 38 and be connected thereto.

As described above, the first field sub-fin 30 and the second field sub-fin 38 may be formed at the same level with respect to the surface of the substrate 10. The first field sub-fin 30 and the second field sub-fin 38 may include the same body as the substrate 10. The first field sub-fin 30 and the second field sub-fin 38 protrude from the second level SL2 to the first level SL1 in a direction perpendicular to the surface of the substrate 10.

The semiconductor stack pattern 36 and the active fin 40 may be formed at the same level in the direction perpendicular to the surface of the substrate 10. Each of the semiconductor stack pattern 36 and the active fin 40 may include an epitaxial layer as a body different from the substrate 10. The active fin 40 may be at a higher level than the first field sub-fin 30 in the direction perpendicular to the surface of the substrate 10. For example, the top of the active fin 40 may be at a level corresponding to the top of the semiconductor stack pattern 36.

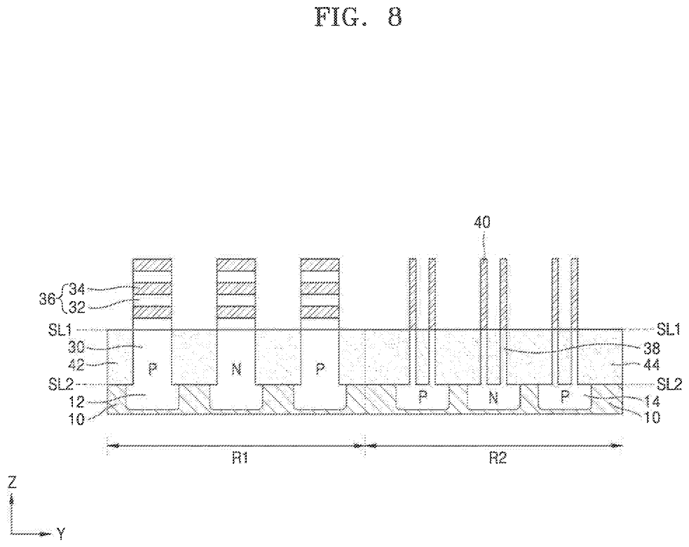

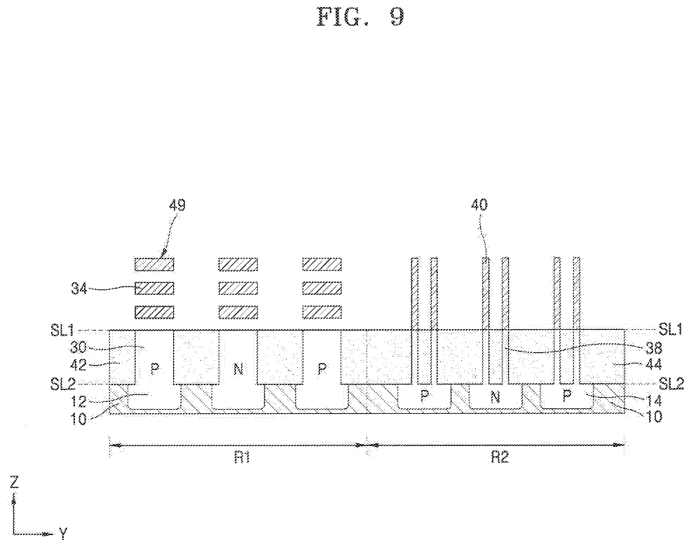

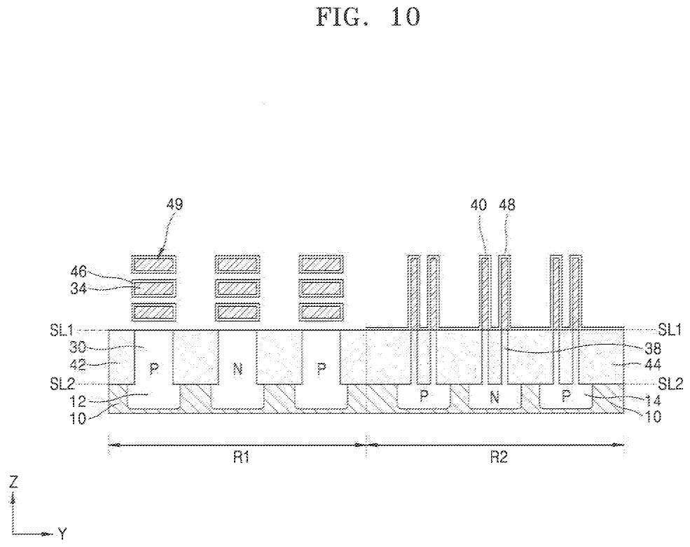

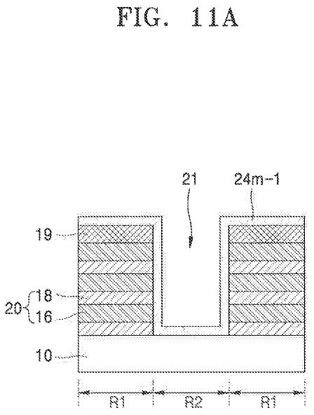

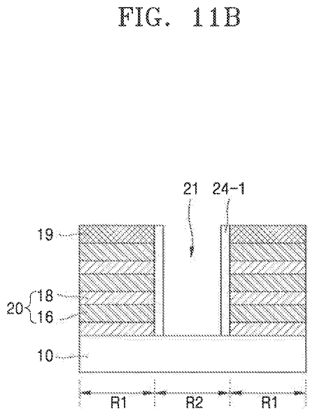

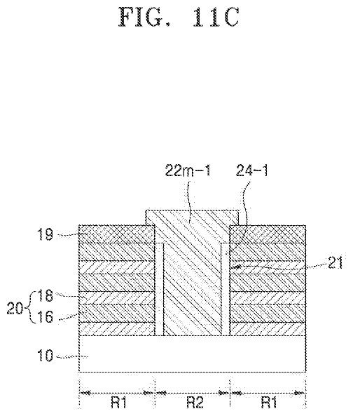

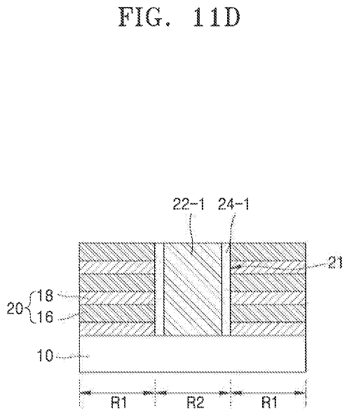

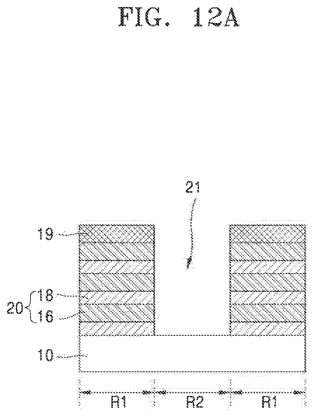

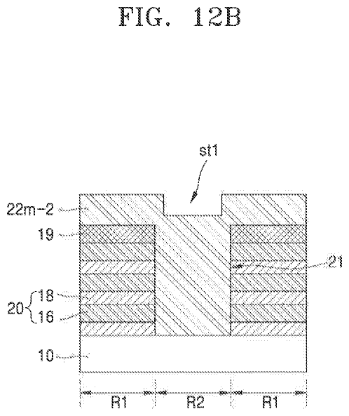

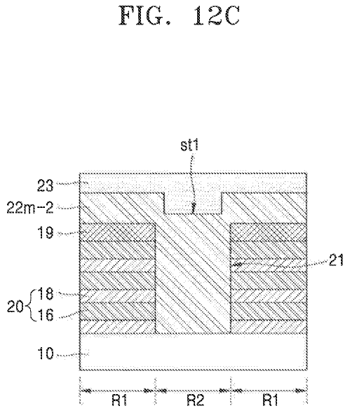

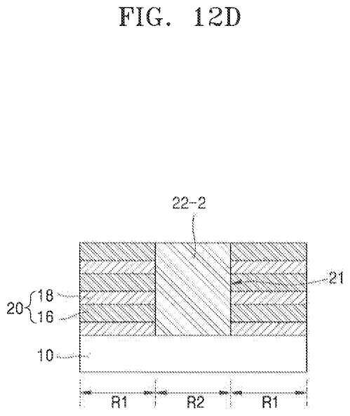

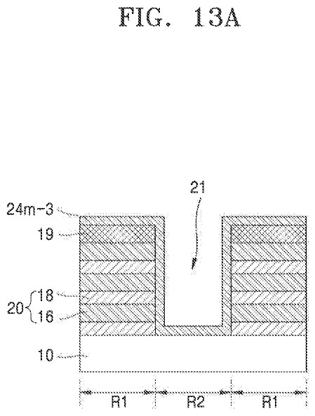

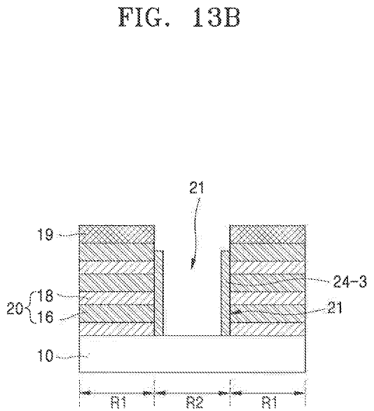

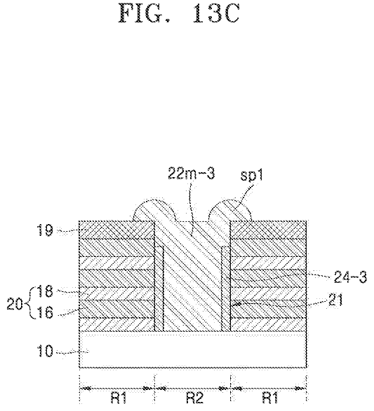

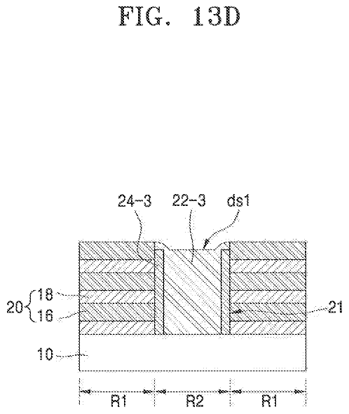

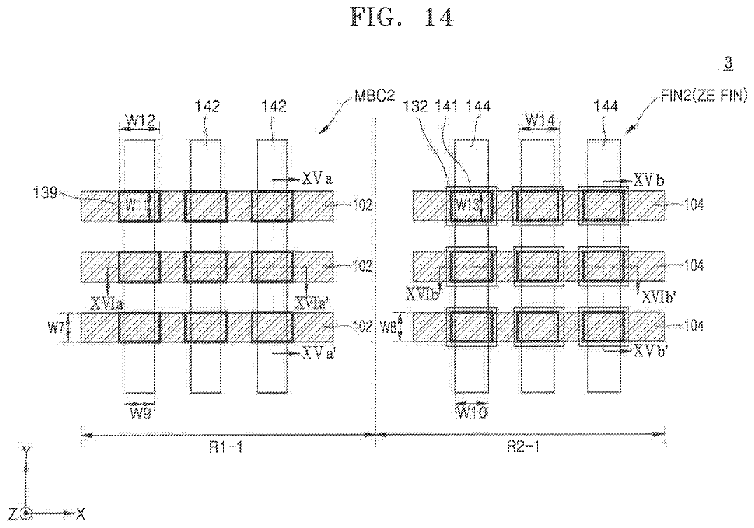

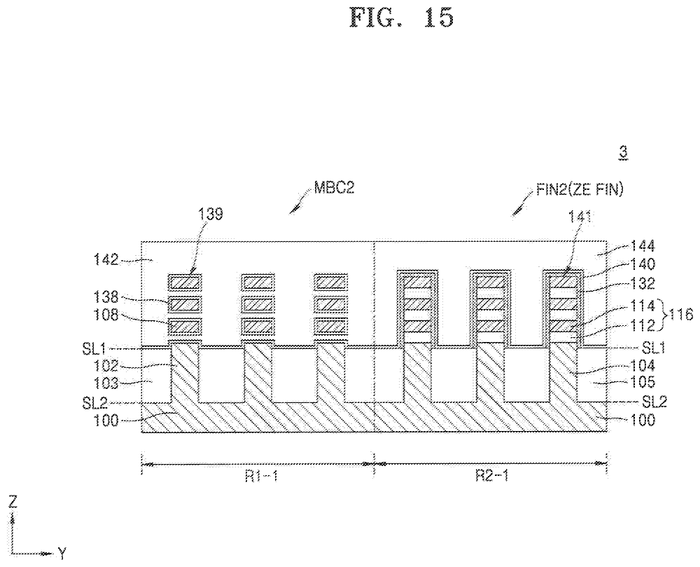

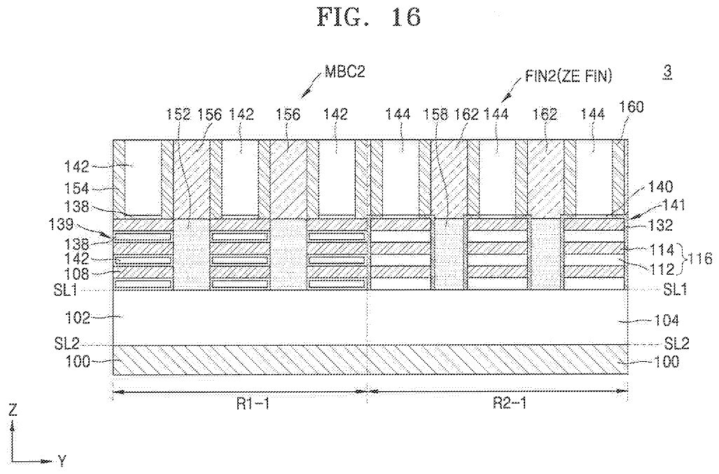

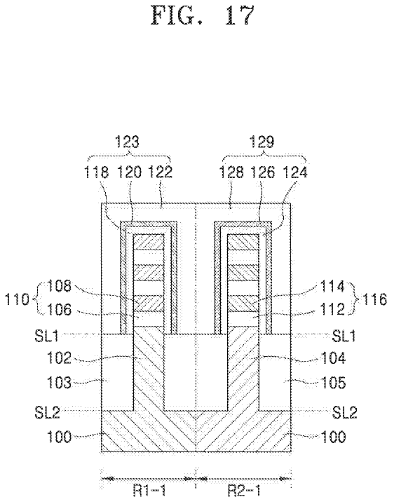

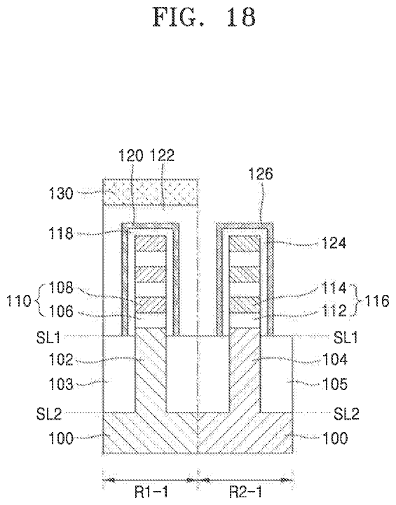

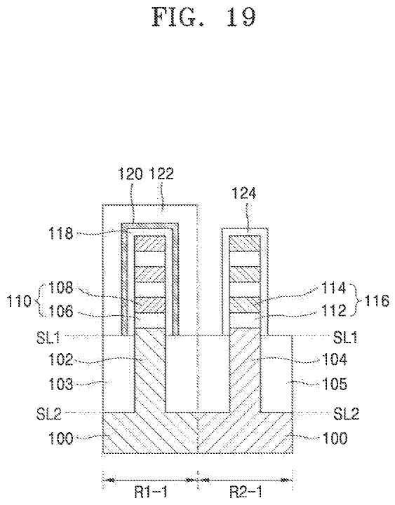

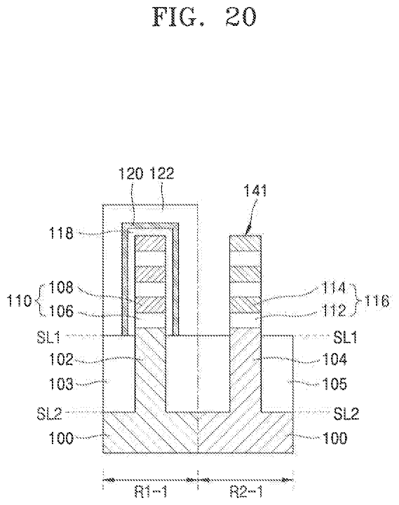

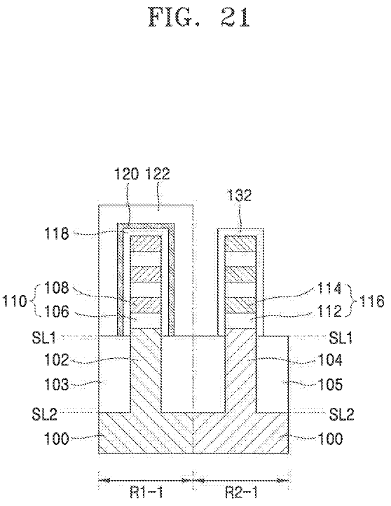

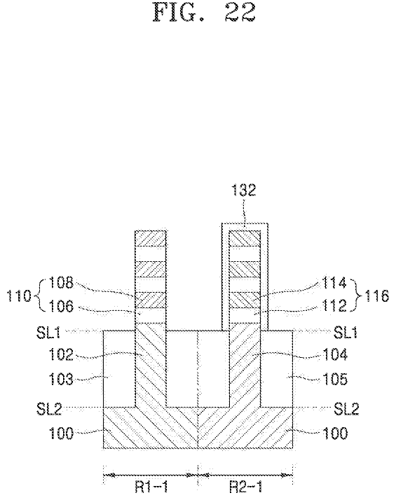

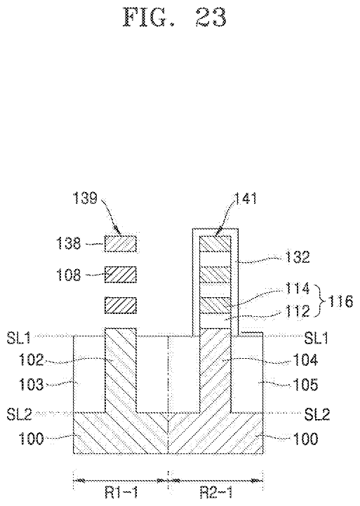

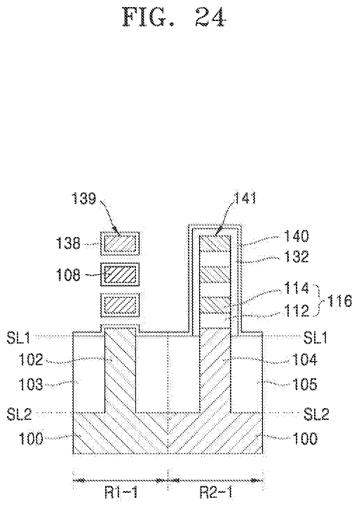

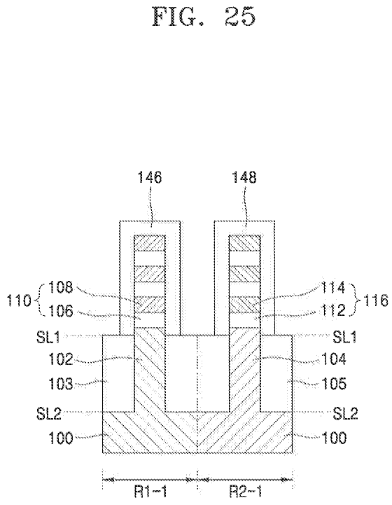

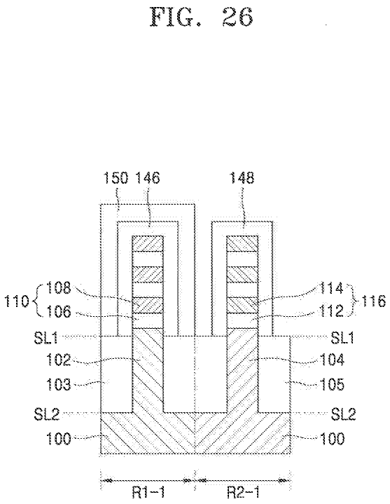

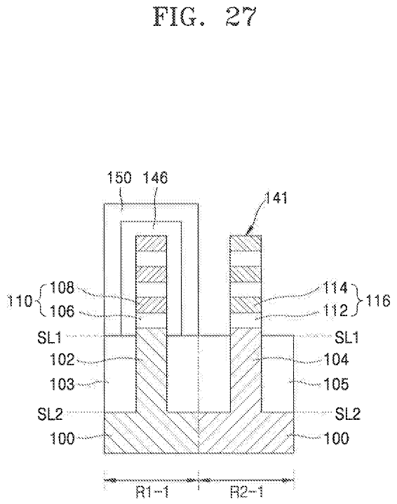

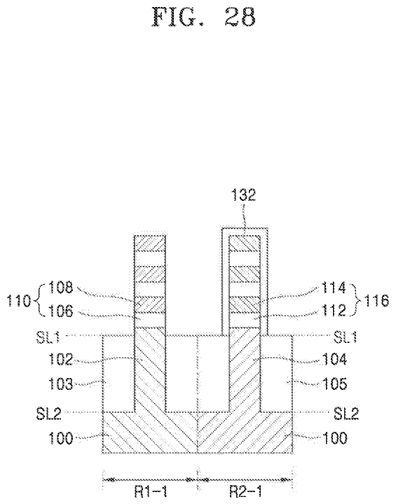

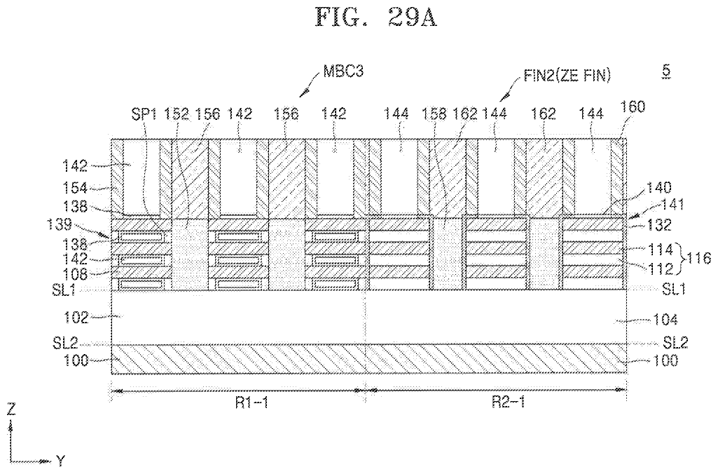

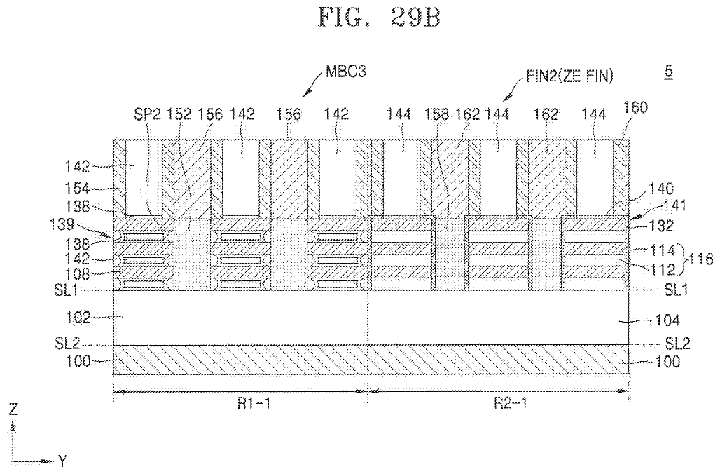

Referring to FIGS. 8 and 9, the first mask pattern 26 and the second mask pattern 28 are removed as shown in FIG. 8. A first device isolation layer 42 is formed to surround the first field sub-fin 30 of the first region R1. A second device isolation layer 44 is formed to surround the second field sub-fin 38 of the second region R2. In some exemplary embodiments of the inventive concept, the surfaces of the first device isolation layer 42 and the second device isolation layer 44 may be at the first level SL1 near the surface of the substrate 10.

As shown in FIG. 9, the first semiconductor pattern 32 of the first region R1 is removed to form the nanosheet stack structure 49. The nanosheet stack structure 49 may have a structure in which the nanosheets 34 are spaced apart from each other and stacked. The nanosheet stack structure 49 may be at the same level as the active fin 40 in the direction perpendicular to the surface of the substrate 10.

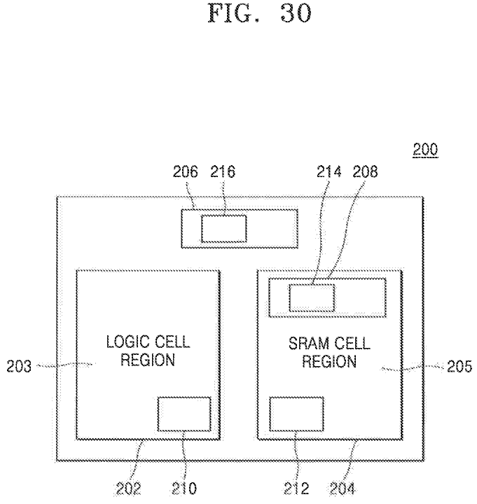

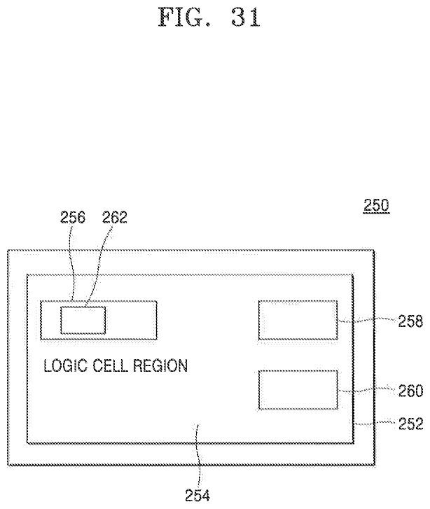

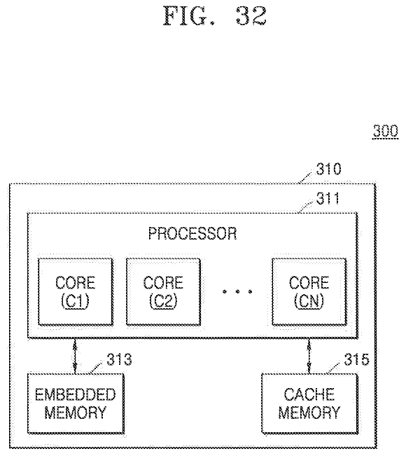

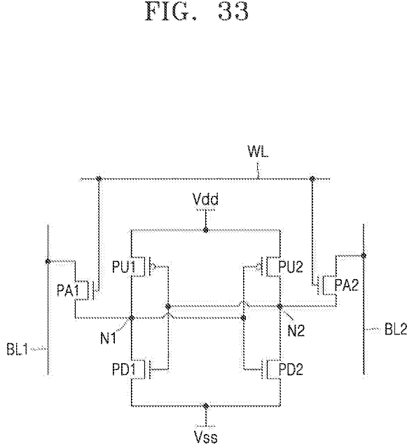

Referring to FIG. 10, a first gate dielectric layer 46 is formed on the surface of each of the nanosheets 34 constituting the nanosheet stack structure 49 in the first region R1. The first gate dielectric layer 46 is formed to surround each of the nanosheets 34. A second gate dielectric layer 48 is formed on the surface and sidewalls of the active fin 40 in the second region R2. In some exemplary embodiments of the inventive concept, the first gate dielectric layer 46 and the second gate dielectric layer 48 may be simultaneously formed.

When the first gate dielectric layer 46 and the second gate dielectric layer 48 are formed simultaneously or separately, the first gate dielectric layer 46 may be formed in a space between the nanosheets 34 because the active fin 40 is in the form of a fin.

Subsequently, as shown in FIG. 2, in the first region R1, a first gate electrode 50 is formed on the first gate dielectric layer 46 and between first nanosheets 34 through a gate forming process, for example, a replacement gate forming process. In the second region R2, a second gate electrode 52 is formed on the second gate dielectric layer 48.

FIGS. 11A to 11D are cross-sectional views illustrating a process of manufacturing the integrated circuit semiconductor device of FIG. 5, according to an exemplary embodiment of the inventive concept.

For example, in FIGS. 11A to 11D, reference numerals that are the same as those of FIG. 5 denote elements that are the same as those of FIG. 5, and thus, the same descriptions as those given with reference to FIG. 5 are briefly provided or omitted. Referring to FIGS. 11A to 11D, a substrate 10 may include a first region R1 and a second region R2, and the second region R2 is located between first regions R1.

Referring to FIGS. 1A and 11B, as shown in FIG. 11A, a first semiconductor material layer and a second semiconductor material layer are sequentially stacked on the entire surface of the substrate 10 having the first region R1 and the second region R2.

Subsequently, the first semiconductor material layer and a nanosheet semiconductor material layer are etched using a mask pattern 19 to form a semiconductor stack material layer 20, which includes a first semiconductor layer 16 and a nanosheet semiconductor layer 18, in the first region R1. An opening 21 is formed to expose the substrate 10 of the second region R2 between semiconductor stack material layers 20.

Subsequently, a liner material layer 24m-1 is formed on the surface of the substrate 10, the inner walls of the opening 21, sidewalls of the semiconductor stack material layer 20, and the surface of the mask pattern 19. The liner material layer 24m-1 may include a silicon nitride layer.

As shown in FIG. 11B, the liner material layer 24m-1 is etched to form a liner layer 24-1 on the inner walls of the opening 21 and the sidewalls of the semiconductor stack material layer 20. The liner layer 24-1 may correspond to the liner layer 24 of FIG. 2.

Referring to FIGS. 11C and 11D, as shown in FIG. 11C, an active semiconductor material layer 22m-1 is formed to fill the inside of the opening 21. The active semiconductor material layer 22m-1 may be separated from the semiconductor stack material layer 20 by the liner layer 24-1. The active semiconductor material layer 22m-1 may be formed by an epitaxial growth method. The active semiconductor material layer 22m-1 may include a silicon layer.

Referring to FIG. 1D, the active semiconductor material layer 22m-1 is chemically mechanically polished to form an active semiconductor layer 22-1. The active semiconductor layer 22-1 corresponds to the active semiconductor layer 22 of FIG. 5. The mask pattern 19 is removed during or after the formation of the active semiconductor layer 22-1.

FIGS. 12A to 121) are cross-sectional views illustrating a process of manufacturing the integrated circuit semiconductor device of FIG. 5, according to an exemplary embodiment of the inventive concept.

For example, FIGS. 12A to 12D may be the same as FIGS. 11A to 11D except that a liner layer is not formed in the second region R2. In FIGS. 12A to 12D, the same reference numerals as those of FIGS. 5 and 11A to 11D denote the same elements as those of FIGS. 5 and 11A to 11D, and thus, the same descriptions as those given with reference to FIGS. 5 and 11A to 11D are briefly provided or omitted.

Referring to FIGS. 12A and 12B, as shown in FIG. 12A, a semiconductor stack material layer 20 including a first semiconductor layer 16 and a nanosheet semiconductor layer 18 is formed in a first region R1. In the first region R1, a mask pattern 19 used when the semiconductor stack material layer 20 is formed is formed. In a second region R2, an opening 21 is formed to expose a substrate 10 between semiconductor stack material layers 20.

As shown in FIG. 12B, an active semiconductor material layer 22m-2 is formed on the mask pattern 19 while the inside of the opening 21 is filled. The active semiconductor material layer 22m-2 is formed on the surface of the substrate 10 and the surfaces of the semiconductor stack material layer 20 and the mask pattern 19 by a non-selective epitaxial growth method. The active semiconductor material layer 22m-2 may include a silicon layer. Accordingly, a step st1 may be formed between a portion of the active semiconductor material layer 22m-2 formed in the opening 21 and a portion of the active semiconductor material layer 22m-2 formed on the mask pattern 19. The step st1 may be a recess in the active semiconductor material layer 20 overlapping the opening 21.

Referring to FIGS. 12C and 121), as shown in FIG. 12C, a capping layer 23 is formed on the active semiconductor material layer 22m-2 to fill the step st1 located in the opening 21. The capping layer 23 includes a polysilicon layer.

Referring to FIG. 12D, the capping layer 23 and the active semiconductor material layer 22m-2 are chemically mechanically polished to form an active semiconductor layer 22-2. The active semiconductor layer 22-2 may be separated from the semiconductor stack material layer 20 without a liner layer. The active semiconductor layer 22-2 corresponds to the active semiconductor layer 22 of FIG. 5. The mask pattern 19 is removed during or after the formation of the active semiconductor layer 22-2.

FIGS. 13A to 13D are cross-sectional views illustrating a process of manufacturing the integrated circuit semiconductor device of FIG. 5, according to an exemplary embodiment of the inventive concept.

For example, FIGS. 13A to 13D may be the same as FIGS. 11A to 11D except that a liner layer 24-3 includes a silicon oxide layer and a dishing portion ds1 is formed in a second region R2. In FIGS. 13A to 13D, the same reference numerals as those of FIGS. 5 and 11A to 11D denote the same elements as those of FIGS. 5 and 11A to 11D, and thus, the same descriptions as those given with reference to FIGS. 5 and 11A to 11D are briefly provided or omitted.

Referring to FIGS. 13A and 13B, as shown in FIG. 13A, a semiconductor stack material layer 20 including a first semiconductor layer 16 and a nanosheet semiconductor layer 18 is formed in a first region R1. In the first region R1, a mask pattern 19 used when the semiconductor stack material layer 20 is formed is formed. In the second region R2, an opening 21 is formed to expose a substrate 10 between semiconductor stack material layers 20.

Subsequently, a liner material layer 24m-3 is formed on the surface of the substrate 10, the inner walls of the opening 21, sidewalls of the semiconductor stack material layer 20, and the surface of the mask pattern 19. The liner material layer 24m-3 may include a silicon nitride layer.

As shown in FIG. 13B, the liner material layer 24m-3 is etched to form a liner layer 24-3 on the inner walls of the opening 21 and the sidewalls of the semiconductor stack material layer 20. The liner layer 24-3 may correspond to the liner layer 24 of FIG. 5. After the liner material layer 24m-3, such as a silicon oxide layer, is etched, the liner layer 24-3 may not completely cover the sidewall of an uppermost second semiconductor layer 18 on the substrate 10. In other words, at least one sidewall of the uppermost second semiconductor layer 18 on the substrate 10 may be exposed to the outside.

Referring to FIGS. 13C and 131), as shown in FIG. 13C, an active semiconductor material layer 22m-3 is formed to fill the inside of the opening 21. The active semiconductor material layer 22m-3 may be formed by an epitaxial growth method. The active semiconductor material layer 22m-3 may include a silicon layer.

The active semiconductor material layer 22m-3 may be separated from the semiconductor stack material layer 20 by the liner layer 24-3. The active semiconductor material layer 22m-3 may be overgrown since the uppermost second semiconductor layer 18 is exposed to the outside, and thus, an elliptical portion sp1 may be formed on the mask pattern 19 adjacent to the opening 21.

Referring to FIG. 13D, the active semiconductor material layer 22m-3 is chemically mechanically polished to form an active semiconductor layer 22-3. The active semiconductor layer 22-3 corresponds to the active semiconductor layer 22 of FIG. 5. During the chemical mechanical polishing of the active semiconductor material layer 22m-3, a recessed dishing portion ds1 may be formed on the opening 21 due to the active semiconductor material layer 22m-3 of the elliptical portion sp1. In addition, the upper surface of the semiconductor stack material layer 20 and the surface of the active semiconductor layer 22-3 may not be at the same level. The mask pattern 19 is removed during or after the formation of the active semiconductor layer 22-3.

As described above with reference to FIGS. 11A to 11D, 12A to 12D, and 13A to 13D, the substrate 10 may include the first region R1 and the second region R2 with or without the liner layers 24-1 and 24-3, according to exemplary embodiments of the inventive concept. The liner layers 24-1 and 24-3 may include various material layers such as a silicon nitride layer and a silicon oxide layer.

The semiconductor stack material layer 20 including the first semiconductor layer 16 and the nanosheet semiconductor layer 18 may be formed in the first region R1. In addition, active semiconductor layers 22-1, 22-2, and 22-3 may be formed in the second region R2. The semiconductor stack material layer 20 and the active semiconductor layers 22-1, 22-2, and 22-3 may be formed by an epitaxial growth method.

FIG. 14 is a layout diagram of an integrated circuit semiconductor device 3 according to an exemplary embodiment of the inventive concept.

For example, the integrated circuit semiconductor device 3 may be substantially the same as the integrated circuit semiconductor device 1 of FIG. 1 except that a first region R1-1 includes a second multi-bridge channel type transistor MBC2 and a second region R2-1 includes a second fin-type transistor FIN2. The second fin-type transistor FIN2 includes a zebra fin-type transistor ZE FIN.

The first region R1-1 may correspond to the first region R1 of FIG. 1. The second region R2-1 may correspond to the second region R2 of FIG. 1. With respect to FIG. 14, descriptions corresponding to those given with reference to FIG. 1 are briefly provided or omitted. In some exemplary embodiments of the inventive concept, the first region R1-1 may include a logic cell region operating at a low voltage, for example, a voltage less than 1 V, and the second region R2-1 may include an input/output region operating at a high voltage, for example, 1 V or more.

As described above, the first region R1-1 includes the second multi-bridge channel type transistor MBC2, and the second region R2-1 includes the second fin-type transistor FIN2, for example, the zebra fin-type transistor ZE FIN. The zebra fin-type transistor ZE FIN may include a transistor different from that of the general fin-type transistor GE FIN described above.

In FIG. 14, a first direction (X direction) may be a channel length direction, and a second direction (Y direction) may be a channel width direction. Hereinafter, the layout of the integrated circuit semiconductor device 3 will be described in more detail, and the inventive concept is not limited to the layout of FIG. 14.

The second multi-bridge channel type transistor MBC2 of the first region R1-1 may include a first field sub-fin 102 extending in the first direction (X direction). The first field sub-fin 102 may have a seventh width W7 in the second direction (Y direction). A first gate electrode 142 extends on the first field sub-fin 102 in the second direction (Y direction) perpendicular to the first direction. The first gate electrode 142 may have a ninth width W9 in the first direction.

A nanosheet stack structure 139 may be located in an area where the first field sub-fin 102 and the first gate electrode 142 cross each other in the first region R1-1. The nanosheet stack structure 139 may have an eleventh width W1 and a twelfth width W12 in the second direction and the first direction, respectively. The current driving capability of the second multi-bridge channel type transistor MBC2 may be changed by adjusting the seventh width W7, the ninth width W9, the eleventh width W11, and the twelfth width W12.

Although the planar shape of the nanosheet stack structure 139 is illustrated as substantially rectangular, the inventive concept is not limited thereto. For example, the planar shape of the nanosheet stack structure 139 may be circular.

The second fin-type transistor FIN2 of the second region R2-1 may include a second field sub-fin 104 extending in the first direction. The second field sub-fin 104 may be an active region. The second field sub-fin 104 may have an eighth width W8 in the second direction.

In some exemplary embodiments of the inventive concept, the eighth width W8 of the second field sub-fin 104 may be equal to the seventh width W7 of the first field sub-fin 102. In some exemplary embodiments of the inventive concept, the eighth width W8 of the second field sub-fin 104 may be less than the seventh width W7 of the first field sub-fin 102. In other exemplary embodiments of the inventive concept, the eighth width W8 of the second field sub-fin 104 may be greater than the seventh width W7 of the first field sub-fin 102.

A second gate electrode 144 extends in the second direction (Y direction) perpendicular to the first direction on the second field sub-fin 104. The second gate electrode 144 may have a tenth width W10 in the first direction.

In some exemplary embodiments of the inventive concept, the tenth width W10 of the second gate electrode 144 may be greater than the ninth width W9 of the first gate electrode 142. In this case that the tenth width W10 of the second gate electrode 144 is greater than the ninth width W9 of the first gate electrode 142, the second fin-type transistor FIN2 operates at a higher voltage than the second multi-bridge channel type transistor MBC2.

A zebra-type active fin 141 may be located in an area where the second field sub-fin 104 and the second gate electrode 144 cross each other in the second region R2-1. The zebra-type active fin 141 may have a thirteenth width W13 and a fourteenth width W14 in the second direction and the first direction, respectively. The thirteenth width W13 of the zebra-type active fin 141 may be less than the eleventh width W11 of the nanosheet stack structure 139. The fourteenth width W14 of the zebra-type active fin 141 may be greater than the twelfth width W12 of the nanosheet stack structure 139. The current driving capability of the second fin-type transistor FIN2 may be changed by adjusting the eighth width W8, the tenth width W10, the thirteenth width W13, and the fourteenth width W14.

Although the planar shape of the zebra-type active fin 141 is illustrated as substantially rectangular, the inventive concept is not limited thereto. For example, the planar shape of the zebra-type active fin 141 may be circular.

A zebra cap layer 132 is formed around the zebra-type active fin 141. The zebra-type active fin 141 may be referred to as a zebra-type active fin including the zebra cap layer 132. Since the zebra cap layer 132 is provided, the zebra fin-type transistor ZE FIN may perform an electrical operation more stably.

In the integrated circuit semiconductor device 3 described above, the second multi-bridge channel transistor MBC2 of a three-dimensional transistor is formed in the first region R1-1 on the substrate, in other words, a low voltage operating region. In addition, the second fin-type transistor FIN2 of the three-dimensional transistor, for example, the zebra fin-type transistor ZE FIN is formed in the second region R2-1 on the substrate, in other words, a high voltage operating region. Accordingly, in the integrated circuit semiconductor device 3 according to the present embodiment, three-dimensional transistors operating at a high voltage and a low voltage may be reliably formed as described in more detail below.

FIG. 15 is a cross-sectional view taken along lines XVa-XVa′ and XVb-XVb′ of the integrated circuit semiconductor device 3 of FIG. 14.

For example, as described above, the integrated circuit semiconductor device 3 may be substantially the same as the integrated circuit semiconductor device 1 of FIG. 2 except that the first region R1-1 includes a second multi-bridge channel type transistor MBC2 and the second region R2-1 includes a second fin-type transistor FIN2. The second fin-type transistor FIN2 includes a zebra fin-type transistor ZE FIN.

The first region R1-1 may correspond to the first region R1 of FIG. 2. The second region R2-1 may correspond to the second region R2 of FIG. 2. With respect to FIG. 15, descriptions corresponding to those given with reference to FIG. 2 are briefly provided or omitted.

A first field sub-fin 102 protruding from the surface of a substrate 100 in the third direction (Z direction) may be formed in the first region R1-1. As described above with reference to FIG. 2, a first well region may be formed in the substrate 100. The substrate 100 may include the same material as the substrate 10 of FIG. 2. The first field sub-fin 102 may include the same body as the substrate 100.

The first field sub-fin 102 protrudes from a second level SL2 to a first level SL1 in the third direction (Z direction) on the substrate 100. The first level SL1 may be a level near the surface of the substrate 100. The first field sub-fin 102 may protrude higher than the first level SL1.

A first device isolation layer 103 may be formed on the substrate 100 at sides of the first field sub-fin 102. The first device isolation layer 103 may include the same material as the first device isolation layer 42 of FIG. 2. A nanosheet stack structure 139 is formed on the first field sub-fin 102. The nanosheet stack structure 139 may be at the same level as the zebra-type active fin 141 of the second region R2-1 in the third direction (Z direction), in other words, a direction perpendicular to the surface of the substrate 100. The nanosheet stack structure 139 includes a plurality of first nanosheets 108 spaced apart from each other in the third direction.

In FIG. 15, three first nanosheets 108 are stacked, but more or less nanosheets may be stacked. The number of first nanosheets 108 is not limited. Each of the first nanosheets 108 may include a silicon layer. A first gate dielectric layer 138 is formed to surround the first nanosheets 108. A first gate electrode 142 is formed on the first gate dielectric layer 138 and between the first nanosheets 108.

A second field sub-fin 104 protruding from the surface of the substrate 100 in the third direction (Z direction) may be formed in the second region R2-1. As described above with reference to FIG. 2, a second well region may be formed in the substrate 100. The second field sub-fin 104 may include the same body as the substrate 100.

The second field sub-fin 104 may include a fin type active pattern. The second field sub-fin 104 protrudes from the second level SL2 to the first level SL1 in the third direction (Z direction) on the substrate 100. The second field sub-fin 104 may be at the same level as the first field sub-fin 102 of the first region R1-1 in a direction perpendicular to the surface of the substrate 100. The second field sub-fin 104 may be lower than the first level SL1. The second field sub-fin 104 may also be higher than the first level SL1. The first level SL1 may be a level near the surface of the substrate 100.

A second device isolation layer 105 may be formed on the substrate 100 at sides of the second field sub-fin 104. The second device isolation layer 105 may include the same material as the first device isolation layer 103. The zebra-type active fin 141 connected to the second field sub-fin 104 in the third direction (Z direction), in other words, in the direction perpendicular to the surface of the substrate 100, is formed on the second field sub-fin 104. The zebra-type active fin 141 may be formed as a body different from the substrate 100 or the second field sub-fin 104.

The zebra-type active fin 141 may include a plurality of semiconductor layers, for example, a second semiconductor pattern 112 and a second nanosheet 114. Each of the second semiconductor pattern 112 and the second nanosheet 114 may include an epitaxial layer. The second semiconductor pattern 112 may include a SiGe layer, and the second nanosheet 114 may include a silicon layer.

The zebra-type active fin 141 protrudes from the first level SL1 in the third direction (Z direction) with respect to the surface of the substrate 100. The zebra-type active fin 141 is at a higher level than the first field sub-fin 102 of the first region R1-1 in the third direction (Z direction), in other words, the direction perpendicular to the surface of the substrate 100. A zebra cap layer 132 may be formed to surround the zebra-type active fin 141. The zebra cap layer 132 may include a silicon layer. A second gate dielectric layer 140 is formed on the top surface and side surface of the zebra-type active fin 141. A second gate electrode 144 is formed on the second gate dielectric layer 140.

In some exemplary embodiments of the inventive concept, the first gate dielectric layer 138 of the first region R1-1 and the second gate dielectric layer 140 of the second region R2-1 may be simultaneously formed in a manufacturing process. When the first gate dielectric layer 138 and the second gate dielectric layer 140 are formed simultaneously or separately, the first gate dielectric layer 138 may be easily formed in a space between the first nanosheets 108 because the zebra-type active fin 141 is in the form of a fin.

In some exemplary embodiments of the inventive concept, each of the first gate dielectric layer 138 and the second gate dielectric layer 140 may include a high dielectric layer having a higher dielectric constant than the silicon oxide layer. The first gate dielectric layer 138 and the second gate dielectric layer 140 may include the same material as the first gate dielectric layer 46 and the second gate dielectric layer 48 of FIG. 2.

In some exemplary embodiments of the inventive concept, the first gate electrode 142 of the first region R1-1 and the second gate electrode 144 of the second region R2-1 may be simultaneously formed in a manufacturing process. In some exemplary embodiments of the inventive concept, the first gate electrode 142 and the second gate electrode 144 may include the same material as the first gate electrode 50 and the second gate electrode 52 of FIG. 2.

FIG. 16 is a cross-sectional view taken along lines XVIa-XVIa′ and XVIb-XVIb′ of the integrated circuit semiconductor device 3 of FIG. 14.

For example, the descriptions given with reference to FIG. 15 are briefly provided or omitted. The first field sub-fin 102 may be located on the substrate 100 in the first region R1-1. The first field sub-fin 102 may include the same material as the substrate 100. The first field sub-fin 102 is formed on the substrate 100 from the second level SL2 to the first level SL1 in the third direction (Z direction). The first level SL1 may be a level near the surface of the substrate 100.

The nanosheet stack structure 139 is formed on the first field sub-fin 102. The nanosheet stack structure 139 includes a plurality of nanosheets 108 formed to be spaced apart from each other in the third direction (Z direction). The first gate dielectric layer 138 is formed to surround the nanosheets 108. The first gate electrode 142 is formed on the first gate dielectric layer 138, between the nanosheets 108, and on the nanosheets 108.

In some exemplary embodiments of the inventive concept, a first gate spacer 154 may be formed on both sidewalls of the first gate electrode 142. A first source and drain region 152 may be formed under both sides of the first gate electrode 142 and on both sides of the nanosheet stack structure 139. A first interlayer insulating layer 156 may be formed around the first gate electrode 142 and the first gate spacer 154.

The second field sub-fin 104 may be located on the substrate 100 in the second region R2-1. The second field sub-fin 104 may include a fin type active pattern. The second field sub-fin 104 is formed on the substrate 100 from the second level SL2 to the first level SL1 in the third direction (Z direction).

The zebra-type active fin 141 is formed on the second field sub-fin 104. The zebra-type active fin 141 may include a second semiconductor stack pattern 116, for example, a second semiconductor pattern 112 and a second nanosheet 114. The zebra-type active fin 141 may be at a higher level than the first field sub-fin 102 of the first region R1-1 in the third direction (Z direction), in other words, the direction perpendicular to the surface of the substrate 100.

The zebra cap layer 132 may be formed on both sidewalls and a portion of the surface of the zebra-type active fin 141. For example, the zebra cap layer 132 may cover the zebra-type active fin 141. The zebra cap layer 132 may include a silicon layer. The second gate dielectric layer 140 is formed on a portion of the zebra-type active fin 141. The second gate electrode 144 is formed on the second gate dielectric layer 140.

In some exemplary embodiments of the inventive concept, a second gate spacer 160 may be formed around the second gate electrode 144. Second source and drain regions 158 may be formed under the second gate electrode 144 and on both sides of the zebra-type active fin 141. A second interlayer insulating layer 162 may be formed around the second gate electrode 144 and the second gate spacer 160.

FIGS. 17 to 24 are cross-sectional views illustrating a method of manufacturing the integrated circuit semiconductor device 3 of FIG. 15, according to an exemplary embodiment of the inventive concept.

For example, in FIGS. 17 to 24, the same reference numerals as those of FIGS. 14 and 15 denote the same elements as those of FIGS. 14 and 15, and thus, the same descriptions as those given with reference to FIGS. 14 and 15 are briefly provided or omitted. For convenience of description, as an example, one nanosheet stack structure 139 and one zebra-type active fin 141 are shown in FIGS. 17 to 25.

Referring to FIG. 17, a first field sub-fin 102 and a first device isolation layer 103 surrounding the first field sub-fin 102 are formed in a first region R1-1 of a substrate 100. The first field sub-fin 102 protrudes from a second level SL2 to a first level SL1. The first field sub-fin 102 may protrude higher than the surface of the first device isolation layer 103. For example, the first field sub-fin 102 may protrude above the first level SL1. The first level SL1 may be a level near the surface of the substrate 100.

A second field sub-fin 104 and a second device isolation layer 105 surrounding the second field sub-fin 104 are formed in a second region R2-1 of the substrate 100. The second field sub-fin 104 protrudes from the second level SL2 of the substrate 100 to the first level SL1. The second field sub-fin 104 may protrude higher than the surface of the second device isolation layer 105. For example, the second field sub-fin 104 may protrude above the first level SL1. In some exemplary embodiments of the inventive concept, the first field sub-fin 102 and the second field sub-fin 104 may be formed at the same stage in a manufacturing process. In some exemplary embodiments of the inventive concept, the first field sub-fin 102 and the second field sub-fin 104 may be formed at the same level in a direction perpendicular to the surface of the substrate 100.

A first semiconductor stack pattern 110 in which a first semiconductor pattern 106 and a first nanosheet 108 are alternately stacked multiple times is formed on the first field sub-fin 102 of the first region R1-1. The first semiconductor pattern 106 and the first nanosheet 108 may be formed by an epitaxial growth method. The first semiconductor pattern 106 and the first nanosheet 108 may include different semiconductor materials.

In some exemplary embodiments of the inventive concept, the first semiconductor pattern 106 may include SiGe and the first nanosheet 108 may include Si, but they are not limited thereto. The first semiconductor pattern 106 and the first nanosheet 108 may have the same thickness, but the inventive concept is not limited thereto.

A second semiconductor stack pattern 116 in which a second semiconductor pattern 112 and a second nanosheet 114 are alternately stacked multiple times is formed on the second field sub-fin 104 of the second region R2-1. The second semiconductor stack pattern 116 of the second region R2-1 may constitute a zebra-type active fin 141, as described below. The second semiconductor pattern 112 and the second nanosheet 114 may be formed by an epitaxial growth method. The second semiconductor pattern 112 and the second nanosheet 114 may include different semiconductor materials.

In some exemplary embodiments of the inventive concept, the second semiconductor pattern 112 may include SiGe and the second nanosheet 114 may include Si, but they are not limited thereto. The second semiconductor pattern 112 and the second nanosheet 114 may have the same thickness, but the inventive concept is not limited thereto.

The first semiconductor stack pattern 110 and the second semiconductor stack pattern 116 may be formed on the first level SL1 of the substrate 100. In some exemplary embodiments of the inventive concept, the first semiconductor stack pattern 110 and the second semiconductor stack pattern 116 may be formed at the same stage in the manufacturing process. In some exemplary embodiments of the inventive concept, the first semiconductor stack pattern 110 and the second semiconductor stack pattern 116 may be formed at the same level in the direction perpendicular to the surface of the substrate 100.

A first blocking layer 123 is formed to cover the first semiconductor stack pattern 110 of the first region R1-1. The first blocking layer 123 includes a first silicon oxide layer 118, a first silicon nitride layer 120, and a second silicon oxide layer 122.

A second blocking layer 129 is formed to cover the second semiconductor stack pattern 116 of the second region R2-1. The second blocking layer 129 includes a third silicon oxide layer 124, a second silicon nitride layer 126, and a fourth silicon oxide layer 128. In some exemplary embodiments of the inventive concept, the first blocking layer 123 and the second blocking layer 129 may be formed at the same step in the manufacturing process.

Referring to FIGS. 18 and 19, as shown in FIG. 18, a first mask pattern 130 is formed on the first blocking layer 123 of the first region R1-1. The first mask pattern 130 may include a hard mask pattern. The hard mask pattern may include silicon nitride, polysilicon, an SOH material, or a combination thereof, but it is not limited thereto.

Subsequently, the fourth silicon oxide layer 128 of the second region R2-1 is removed using the first mask pattern 130 as an etch mask. In this case, only the third silicon oxide layer 124 and the second silicon nitride layer 126 of the second blocking layer 129 remain in the second region R2-1.

Referring to FIGS. 19 and 20, as shown in FIG. 19, the first mask pattern 130 is removed, and then, the second silicon nitride layer 126 remaining in the second region R2-1 is removed by wet etching. In some exemplary embodiments of the inventive concept, the second silicon nitride layer 126 remaining in the second region R2-1 may be removed using a phosphoric acid solution.

Subsequently, as shown in FIG. 20, the third silicon oxide layer 124 remaining in the second region R2-1 is removed by wet etching. In some exemplary embodiments of the inventive concept, the third silicon oxide layer 124 remaining in the second region R2-1 may be removed by a buffered oxide etchant (BOE) solution.

When the third silicon oxide layer 124 is removed, the second silicon oxide layer 122 of the first region R1-1 may also be partially etched. In this case, a zebra-type active fin 141 including the second semiconductor stack pattern 116 may be formed on the second field sub-fin 104 in the second region R2-1. The zebra-type active fin 141 may be at a level higher than the first field sub-fin 102 in the direction perpendicular to the surface of the substrate 100.

Referring to FIGS. 21 and 22, a zebra cap layer 132 is formed to cover the zebra-type active fin 141, as shown in FIG. 21. The zebra cap layer 132 may be formed by an epitaxial growth method. The zebra cap layer 132 may include a silicon layer.

As shown in FIG. 22, using the zebra cap layer 132 as a mask, the second silicon oxide layer 122, the first silicon nitride layer 120, and the first silicon oxide layer 118 in the first region R1-1 are sequentially removed by using a wet etching method.

The second silicon oxide layer 122, the first silicon nitride layer 120, and the first silicon oxide layer 118 may be removed by a phosphoric acid solution or a BOE solution as described above. In this case, only the first semiconductor stack pattern 110 remains on the first field sub-fin 102 of the second region R2-1.

Referring to FIGS. 23 and 24, as shown in FIG. 23, the first semiconductor pattern 106 is selectively removed from the first semiconductor stack pattern 110 of the first region R1-1. In this case, the nanosheet stack structure 139 may be formed in the first region R1-1. The nanosheet stack structure 139 may have a structure in which the first nanosheets 108 are spaced apart from each other and stacked. The nanosheet stack structure 139 may be at the same level as the zebra-type active fin 141 in the direction perpendicular to the surface of the substrate 100.

As shown in FIG. 24, the first gate dielectric layer 138 is formed on the surfaces of the first nanosheets 108 constituting the nanosheet stack structure 139 in the first region R1-1. The first gate dielectric layer 138 surrounds the first nanosheets 108. The second gate dielectric layer 140 is formed to surround the zebra-type active fin 141 and the zebra cap layer 132 in the second region R2-1. In some exemplary embodiments of the inventive concept, the first gate dielectric layer 138 and the second gate dielectric layer 140 may be simultaneously formed.

When the first gate dielectric layer 138 and the second gate dielectric layer 140 are formed simultaneously or separately, the first gate dielectric layer 138 may be easily formed in a space between the first nanosheets 108 because the zebra-type active fin 141 and the zebra cap layer 132 are in the form of a fin.

Subsequently, as shown in FIG. 15, in the first region R1-1, a first gate electrode 142 is formed on the first gate dielectric layer 138 and between the first nanosheets 34 through a gate forming process, for example, a replacement gate forming process. In the second region R2-2, a second gate electrode 144 is formed on the second gate dielectric layer 140.

FIGS. 25 to 28 are cross-sectional views illustrating a method of manufacturing the integrated circuit semiconductor device 3 of FIG. 15, according to an exemplary embodiment of the inventive concept.

For example, FIGS. 25 to 28 may be the same as FIGS. 17 to 24 except that a first blocking layer 146 and a second blocking layer 148 includes a silicon oxide layer. In FIGS. 25 to 28, the same reference numerals as those of FIGS. 17 to 24 denote the same elements as those of FIGS. 17 to 24, and thus, the same descriptions as those given with reference to FIGS. 17 to 24 are briefly provided or omitted.

Referring to FIGS. 25 and 26, as shown in FIGS. 17 and 25, a first field sub-fin 102, a first device isolation layer 103, and a first semiconductor stack pattern 110 are formed in a first region R1-1 of a substrate 100. A second field sub-fin 104, a second device isolation layer 105, and a second semiconductor stack pattern 116 are formed in a second region R2-1 of the substrate 100.

The first blocking layer 146 is formed to cover the first semiconductor stack pattern 110 of the first region R1-1. The first blocking layer 146 includes a silicon oxide layer. The second blocking layer 148 is formed to cover the second semiconductor stack pattern 116 of the second region R2-1. The second blocking layer 148 includes a silicon oxide layer.

As shown in FIG. 26, a first mask pattern 150 is formed on the first blocking layer 146 of the first region R1-1. The first mask pattern 150 may include a hard mask pattern. The hard mask pattern may include silicon nitride, polysilicon, an SOH material, or a combination thereof, but it is not limited thereto.

Referring to FIGS. 27 and 28, as shown in FIG. 27, the second blocking layer 148 of the second region R2-1 is removed by a wet etching method using the first mask pattern 150 as an etch mask. In this case, a zebra-type active fin 141 including the second semiconductor stack pattern 116 may be formed on the second field sub-fin 104 in the second region R2-1.

As shown in FIG. 28, after the first mask pattern 150 is removed, a zebra cap layer 132 is formed to cover the zebra-type active fin 141. The zebra cap layer 132 may be formed by an epitaxial growth method. The zebra cap layer 132 may include a silicon layer. Next, the first blocking layer 146 of the first region R1-1 is removed. In this case, the first semiconductor stack pattern 110 is exposed.

Next, as shown in FIGS. 23 and 24, a nanosheet stack structure 139 and a first gate dielectric layer 138 are formed in the first region R1-1. A second gate dielectric layer 140 is formed in the second region R2-1 to surround the zebra-type active fin 141 and the zebra cap layer 132.

Subsequently, as shown in FIG. 15, in the first region R1-1, a first gate electrode 142 is formed on the first gate dielectric layer 138 and between the first nanosheets 108. In the second region R2-1, a second gate electrode 144 is formed on the second gate dielectric layer 140.

FIGS. 29A and 29B are cross-sectional views of an integrated circuit semiconductor device 5 according to an exemplary embodiment of the inventive concept.

For example, the integrated circuit semiconductor device 5 of FIGS. 29A and 29B is the same as the integrated circuit semiconductor device 3 of FIG. 16 except that the integrated circuit semiconductor device 5 includes a third multi-bridge channel type transistor MBC3 having gate spacers SP1 and SP2 on both sidewalls of the first gate electrode 142 between the first nanosheets 108. With respect to FIGS. 29A and 29B, the same descriptions as those given above with reference to FIG. 16 are omitted.

In the gate spacer SP1 of the third multi-bridge channel type transistor MBC3 of FIG. 29A, one sidewall facing the first gate electrode 142 has a straight shape. In the gate spacer SP2 of the third multi-bridge channel type transistor MBC3 of FIG. 29B, one sidewall facing the first gate electrode 142 is rounded. The shape of the one sidewall of each of the gate spacers SP1 and SP2 may be variously made according to a manufacturing process.

The integrated circuit semiconductor device 5 of FIGS. 29A and 29B may include a second fin-type transistor FIN2, for example, a zebra fin-type transistor ZE FIN. The zebra fin-type transistor ZE FIN may not include gate spacers on both sidewalls of a second semiconductor pattern 112 between second nanosheets 114.

In some exemplary embodiments of the inventive concept, the third multi-bridge channel type transistor MBC3 may include an N-type metal oxide semiconductor (NMOS) transistor, and the second fin-type transistor FIN2 may be P-type metal oxide semiconductor (PMOS) transistors. As described above, the integrated circuit semiconductor device 5 may reduce parasitic capacitance by including the gate spacers SP1 and SP2 on both sidewalls of the first gate electrode 142 between the first nanosheets 108.

FIG. 30 is a block diagram of a semiconductor chip 200 including an integrated circuit semiconductor device according to exemplary embodiments of the inventive concept.

For example, the semiconductor chip 200 may include a logic region 202, a static random access memory (SRAM) region 204, and an input/output region 206. The logic region 202 may include a logic cell region 203. The SRAM region 204 may include an SRAM cell region 205 and an SRAM peripheral circuit region 208. A first transistor 210 may be arranged in the logic cell region 203, and a second transistor 212 may be arranged in the SRAM cell region 205. A third transistor 214 may be arranged in the SRAM peripheral circuit region 208, and a fourth transistor 216 may be arranged in the input/output region 206.

The semiconductor chip 200 may include the integrated circuit semiconductor device 1 or 3 according to the above described exemplary embodiments of the inventive concept. In some exemplary embodiments of the inventive concept, each of the first transistor 210 and the second transistor 212 may include the first multi-bridge channel type transistor MBC1 or the second multi-bridge channel type transistor MBC2 described above.

In some exemplary embodiments of the inventive concept, the third transistor 214 and the fourth transistor 216 may include the general fin-type transistor FIN1 (GE FIN) or the zebra fin-type transistor FIN2 (ZE FIN) described above.

FIG. 31 is a block diagram of a semiconductor chip 250 including an integrated circuit semiconductor device according to exemplary embodiments of the inventive concept.

For example, the semiconductor chip 250 may include a logic region 252. The logic region 252 may include a logic cell region 254 and an input/output region 256. A first transistor 258 and a second transistor 260 may be arranged in the logic cell region 254. The first transistor 258 and the second transistor 260 may be transistors of different conductivity types. A third transistor 262 may be arranged in the input/output region 256.

The semiconductor chip 250 may include the integrated circuit semiconductor device 1, 3, or 5 according to the above described exemplary embodiments of the inventive concept. In some exemplary embodiments of the inventive concept, each of the first transistor 258 and the second transistor 260 may include the first multi-bridge channel type transistor MBC1 or the second multi-bridge channel type transistor MBC2 described above. In some exemplary embodiments of the inventive concept, the third transistor 262 may include the general fin-type transistor FIN1 (GE FIN) or the zebra fin-type transistor FIN2 (ZE FIN) described above.

FIG. 32 is a block diagram of an electronic device 300 including an integrated circuit semiconductor device according to exemplary embodiments of the inventive concept.

For example, the electronic device 300 may include a system on chip (SOC) 310. The SOC 310 may include a processor 311, an embedded memory 313, and a cache memory 315. The processor 311 may include one or more processor cores C1-Cn. The processor cores C1-Cn may process data and signals. The processor cores C1-Cn may include the integrated circuit semiconductor device 1, 3, or 5 according to the above described exemplary embodiments of the inventive concept.

The electronic device 300 may perform its own functions by using the processed data and signals. In an example, the processor 311 may include an application processor. The embedded memory 313 may exchange first data DAT1 with the processor 311. The first data DAT1 may be data processed or to be processed by the processor cores C-Cn. The embedded memory 313 may manage the first data DAT1. For example, the embedded memory 313 may buffer the first data DAT1. The embedded memory 313 may operate as a buffer memory or a working memory of the processor 311.

The embedded memory 313 may include SRAM. The SRAM may operate faster than dynamic random access memory (DRAM). When the SRAM is embedded in the SOC 310, the electronic device 300 having a small size and operating at a high speed may be realized. Further, when the SRAM is embedded in the SOC 310, the consumption of the active power of the electronic device 300 may be reduced.

In an example, the SRAM may include the integrated circuit semiconductor device 1 or 3 according to the above described exemplary embodiments of the inventive concept. The cache memory 315 may be mounted on the SOC 310 together with the processor cores C1-Cn. The cache memory 315 may store cache data DATc. The cache data DATc may include data used by the processor cores C1-Cn. The cache memory 315 may have a small storage capacity, but may operate at a very high speed.

For example, the cache memory 315 may include the SRAM including the integrated circuit semiconductor device 1, 3, or 5 according to the above described exemplary embodiments of the inventive concept. When the cache memory 315 is used, the number of times the processor 311 accesses the embedded memory 313 and the time during which the processor 311 accesses the embedded memory 313 may be reduced. Therefore, when the cache memory 315 is used, the operation speed of the electronic device 300 may be increased. In FIG. 32, the cache memory 315 is shown as a separate component from processor 311, for ease of understanding. However, the cache memory 315 may be configured to be included in the processor 311.

FIG. 33 is an equivalent circuit diagram of an SRAM cell according to exemplary embodiments of the inventive concept.

For example, the SRAM cell may be implemented by using the integrated circuit semiconductor device 1, 3, or 5 according to the above described exemplary embodiments of the inventive concept. For example, the SRAM cell may be applied to the embedded memory 313 and/or the cache memory 315 illustrated in FIG. 32.

The SRAM cell may include a first pull-up transistor PU1, a first pull-down transistor PD1, a second pull-up transistor PU2, a second pull-down transistor PD2, a first access transistor PA1, and a second access transistor PA2.

The first and second pull-up transistors PU1 and PU2 may be P-type MOS transistors while the first and second pull-down transistors PD1 and PD2 and the first and second access transistors PA1 and PA2 may be N-type MOS transistors.

The first pull-up transistor PU1 and the first pull-down transistor PD1 may constitute a first inverter. The gate electrodes (e.g., gates) of the first pull-up and first pull-down transistors PU1 and PD1 connected to each other, may correspond to an input terminal of the first inverter, and a first node N1 may correspond to an output terminal of the first inverter.

The second pull-up transistor PU2 and the second pull-down transistor PD2 may constitute a second inverter. The gate electrodes (e.g., gates) of the second pull-up and second pull-down transistors PU2 and PD2 connected to each other, may correspond to an input terminal of the second inverter and a second node N2 may correspond to an output terminal of the second inverter.

The first and second inverters may be combined to constitute a latch structure. The gate electrodes of the first pull-up and first pull-down transistors PU1 and PD1 may be electrically connected to the second node N2 and the gates of the second pull-up and second pull-down transistors PU2 and PD2 may be electrically connected to the first node N.

A first source/drain of the first access transistor PA1 may be connected to the first node N1 and a second source/drain of the first access transistor PA1 may be connected to a first bit line BL1. A first source/drain of the second access transistor PA2 may be connected to the second node N2 and a second source/drain of the second access transistor PA2 may be connected to a second bit line BL2.

The gate electrodes of the first and second access transistors PA1 and PA2 may be electrically connected to a word line WL. Accordingly, the SRAM cell may be implemented using the integrated circuit semiconductor device 1 or 3 according to the above described exemplary embodiments of the inventive concept.

In an integrated circuit semiconductor device according to the above described exemplary embodiments of the inventive concept, a first multi-bridge channel transistor of a three-dimensional transistor is formed in a first region of a substrate, in other words, a low voltage operating region. A fin-type transistor of the three-dimensional transistor, for example, a general fin-type transistor having a general active fin or a zebra fin-type transistor having a zebra-type active pin, is formed in a second region of the substrate, in other words, a high voltage operating region. Accordingly, in the integrated circuit semiconductor device according to the above described exemplary embodiments of the inventive concept, three-dimensional transistors operating at a high voltage and a low voltage may be reliably formed on the substrate.

While the inventive concept has been particularly shown and described with reference to exemplary embodiments thereof, it will be understood that various changes in form and details may be made thereto without departing from the spirit and scope of the inventive concept as set forth by the following claims.

1. An integrated circuit semiconductor device, comprising:
a multi-bridge channel type transistor in a first region of a substrate,
wherein the multi-bridge channel type transistor comprises a nanosheet stack structure on the substrate, a first gate dielectric layer on the nanosheet stack structure, and a first gate electrode on the first gate dielectric layer; and
a fin-type transistor in a second region of the substrate,
wherein the fin-type transistor comprises an active fin on the substrate, a second gate dielectric layer on the active fin, and a second gate electrode on the second gate dielectric layer,
wherein a width of the nanosheet stack structure is greater than a width of the active fin.

2. The integrated circuit semiconductor device of claim 1, wherein the active fin comprises first and second active fins spaced apart from each other, and the width of the nanosheet stack structure is greater than or equal to a sum of widths of the first and second active fins.

3. The integrated circuit semiconductor device of claim 1, wherein the active fin extends in a first direction, the first gate electrode and the second gate electrode extend in a second direction perpendicular to the first direction,
wherein a width of the first gate electrode in the first direction is less than a width of the second gate electrode in the first direction.

4. The integrated circuit semiconductor device of claim 1, wherein gate spacers are formed on first and second sidewalls of the first gate electrode.

5. The integrated circuit semiconductor device of claim 1, wherein the nanosheet stack structure is at a same level as the active fin in a direction perpendicular to a surface of the substrate.

6. The integrated circuit semiconductor device of claim 1, wherein the active fin comprises a single semiconductor layer.

7. The integrated circuit semiconductor device of claim 1, wherein the active fin comprises a plurality of stacked semiconductor layers.

8. The integrated circuit semiconductor device of claim 7, wherein a cap layer covers the plurality of stacked semiconductor layers.

9. The integrated circuit semiconductor device of claim 1, wherein the active fin comprises a body different from the substrate.

10. An integrated circuit semiconductor device, comprising:
a multi-bridge channel type transistor in a first region of a substrate,
wherein the multi-bridge channel type transistor comprises a first field sub-fin extending on the substrate in a first direction, a nanosheet stack structure on the first field sub-fin, a first gate dielectric layer on the nanosheet stack structure, and a first gate electrode extending on the first gate dielectric layer in a second direction perpendicular to the first direction; and
a fin-type transistor in a second region of the substrate,
wherein the fin-type transistor comprises a second field sub-fin extending in the first direction, an active fin extending on the second field sub-fin in the first direction, a second gate dielectric layer on the active fin, and a second gate electrode extending on the second gate dielectric layer in the second direction,
wherein a width of the nanosheet stack structure in the second direction is greater than a width of the active fin in the second direction.

11. The integrated circuit semiconductor device of claim 10, wherein the active fin comprises two active fins spaced apart from each other, wherein the width of the nanosheet stack structure in the second direction is greater than or equal to a sum of widths of the two active fins in the second direction.

12. The integrated circuit semiconductor device of claim 10, wherein a width of the first gate electrode in the first direction is less than a width of the second gate electrode in the first direction.

13. The integrated circuit semiconductor device of claim 10, wherein the nanosheet stack structure is at a same level as the active fin in a third direction perpendicular to a surface of the substrate.

14. The integrated circuit semiconductor device of claim 10, wherein the second field sub-fin comprises a same body as the substrate, and the active fin comprises a body different from the second field sub-fin.

15. The integrated circuit semiconductor device of claim 10, wherein the nanosheet stack structure is formed in an area where the first field sub-fin and the first gate electrode cross each other.

16. An integrated circuit semiconductor device, comprising:
a multi-bridge channel type transistor in a first region of a substrate,
wherein the multi-bridge channel type transistor comprises a first field sub-fin extending on the substrate in a first direction, a first gate electrode extending on the first field sub-fin in a second direction perpendicular to the first direction, a nanosheet stack structure overlapping an area where the first field sub-fin and the first gate electrode cross each other, and a first gate dielectric layer between nanosheets of the nanosheet stack structure and the first gate electrode; and
a fin-type transistor in a second region of the substrate,
wherein the fin-type transistor comprises a second field sub-fin extending on the substrate in the first direction, a second gate electrode extending on the second field sub-fin in the second direction, an active fin overlapping an area where the second field sub-fin and the second gate electrode cross each other, and a second gate dielectric layer between the active fin and the second gate electrode,
wherein a width of the nanosheet stack structure in the second direction is greater than a width of the active fin in the second direction.

17. The integrated circuit semiconductor device of claim 16, wherein a width of the first gate electrode in the first direction is less than a width of the second gate electrode in the first direction,
wherein gate spacers are formed on first and second sidewalls of the first gate electrode.

18. The integrated circuit semiconductor device of claim 16, wherein the nanosheet stack structure is at a same level as the active fin in a third direction perpendicular to a surface of the substrate.

19. The integrated circuit semiconductor device of claim 16, wherein the second field sub-fin comprises a same body as the substrate, and the active fin comprises a body different from the second field sub-fin.

20. The integrated circuit semiconductor device of claim 16, wherein the first region includes a logic cell region that operates at less than one volt and the second region includes an input/output region that operates at equal to or greater than one volt.

21-24. (canceled)
